(19) United States
(12) Patent Application Publication
(10) Pub. No.: US 2010/0279213 A1
(43) Pub. Date: Nov. 4, 2010

(54) METHODS AND SYSTEMS FOR CONTROLLING VARIATION IN DIMENSIONS OF PATTERNED FEATURES ACROSS A WAFER

(75) Inventors: Ady Levy, Sunnyvale, CA (US); Michael Hanna, La Canada, CA (US); Dan Wack, Los Altos, CA (US); John Fielden, Los Altos, CA (US); Christopher F. Bevis, Los Gatos, CA (US); Larry Wagner, San Jose, CA (US)

Correspondence Address: Entropy Matters LLC, P.O. Box 2250, NEW YORK, NY, 10021, US

(73) Assignee: KLA-TENCOR CORPORATION, Milpitas, CA (US)

(21) Appl. No.: 12/778,994

(22) Filed: May 12, 2010

Related U.S. Application Data
(63) Continuation-in-part of application No. 11/314,638, filed on Dec. 20, 2005, now abandoned.
Application No. 11/314,638 is a continuation-in-part of application No. 12/328,123, filed on Dec. 4, 2008, now Pat. No. 7,767,956.
Application No. 12/328,123 is a continuation of application No. 11/345,145, filed on Feb. 1, 2006, now Pat. No. 7,462,814.
Application No. 11/345,145 is a continuation of application No. 10/401,509, filed on Mar. 27, 2003, now abandoned.
Application No. 10/401,509 is a continuation of application No. 09/849,622, filed on May 4, 2001, now Pat. No. 6,689,519.
(60) Provisional application No. 60/638,857, filed on Dec. 22, 2004.
(60) Provisional application No. 60/202,372, filed on May 4, 2000.

(51) Int. Cl. G03F 7/20; G03B 27/52

(52) U.S. Cl. 430/30; 355/30

(57) ABSTRACT

Methods and systems for controlling variation in dimensions of patterned features across a wafer are provided. One method includes measuring a characteristic of a latent image formed in a resist at more than one location across a wafer during a lithography process. The method also includes altering a parameter of the lithography process in response to the characteristic to reduce variation in dimensions of patterned features formed across the wafer by the lithography process. Altering the parameter compensates for non-time varying spatial variation in a temperature to which the wafer is exposed during a post exposure bake step of the lithography process and an additional variation in the post exposure bake step.

### CROSS-REFERENCE TO RELATED APPLICATIONS

This application is a continuation-in-part of U.S. patent application Ser. No. 11/314,638 entitled “Methods and Systems for Controlling Variation in Dimensions of Patterned Features Across a Wafer,” filed Dec. 20, 2005 abandoned May 13, 2010, which claims priority to U.S. Provisional Application Ser. No. 60/638,857 entitled “Methods and Systems for Controlling the Repeatability and Uniformity of Lithographic Pattern Dimensions,” filed Dec. 22, 2004, both of which are incorporated by reference as if fully set forth herein. This application is also a continuation-in-part of U.S. patent application Ser. No. 12/328,123 entitled “Methods and Systems for Lithography Process Control,” filed Dec. 4, 2008, which is a continuation of U.S. patent application Ser. No. 11/345,145 entitled “Methods and Systems for Lithography Process Control,” filed Feb. 1, 2006, now U.S. Pat. No. 7,462,814, which is a continuation of U.S. patent application Ser. No. 10/401,509 entitled “Methods and Systems for Lithography Process Control,” filed Mar. 27, 2003, now abandoned, which is a continuation of U.S. patent application Ser. No. 09/849,622 entitled “Methods and Systems for Lithography Process Control,” filed May 4, 2001, now U.S. Pat. No. 6,689,519, which claims priority to U.S. Provisional Application Ser. No. 60/202,372 entitled “Methods and Systems for Lithography Process Control,” filed May 4, 2000, all of which are incorporated by reference as if fully set forth herein.

### BACKGROUND OF THE INVENTION

1. Field of the Invention

This invention generally relates to methods and systems for controlling variation in dimensions of patterned features across a wafer. Certain embodiments relate to altering a parameter of a lithography process in response to a characteristic of a latent image measured at more than one location across a wafer to reduce variation in dimensions of patterned features formed across the wafer by the lithography process.

2. Description of the Related Art

The following description and examples are not admitted to be prior art by virtue of their inclusion in this section.

Semiconductor fabrication processes involve a number of lithography steps to form various features and multiple levels of a semiconductor device. Lithography involves transferring a pattern to a resist formed on a semiconductor substrate, which may be commonly referred to as a wafer. A reticle, or a mask, is disposed above the resist and typically has substantially transparent regions and substantially opaque regions configured in a pattern that is transferred to the resist. In particular, substantially opaque regions of the reticle protect underlying regions of the resist from exposure to an energy source. The resist is, therefore, patterned by selectively exposing regions of the resist to an energy source such as ultraviolet light. The patterned resist may then be used to mask underlying layers in subsequent semiconductor fabrication processes such as ion implantation and etch. For example, a resist may substantially inhibit an underlying layer such as a dielectric material or the semiconductor substrate from implantation of ions or removal by etch.

As the feature sizes of semiconductor devices continue to shrink, the minimum feature size that may be successfully fabricated may often be limited by performance characteristics of a lithography process. Examples of performance characteritics of a lithography process include, but are not limited to, resolution capability, across chip linewidth variations, and across wafer linewidth variations. In optical lithography, performance characteristics such as resolution capability of the lithography process may often be limited by the quality of the resist application, the performance of the resist, the exposure tool, and the wavelength of light that is used to expose the resist. The ability to resolve a minimum feature size, however, may also be strongly dependent on other critical parameters of the lithography process such as a temperature of a post exposure bake (PEB) process or an exposure dose of an exposure process. As such, controlling the critical parameters of lithography processes is becoming increasingly important to the successful fabrication of semiconductor devices.

One strategy for improving the performance characteristics of a lithography process involves controlling and reducing variations in critical parameters of the lithography process. One critical parameter in a lithography process is the PEB temperature. For example, a chemical reaction in an exposed portion of a chemically amplified resist is driven and controlled by heating the resist subsequent to the exposure process. Such a resist may include, but is not limited to, a resin and a photo-acid generating (PAG) compound. In such a resist, the temperature of the PEB process drives generation and diffusion of a photo-generated acid in the resist that causes deblocking of the resin. Deblocking of the resin substantially alters the solubility of the resist such that it may be removed by exposure to an aqueous developer solution in a subsequent developing process. As such, temperature-controlled diffusion in the exposed resist affects physical dimensions of the remaining resist, or resolved patterned features. Furthermore, variations in temperature across a bake plate of a PEB process module may cause variations in the dimensions of the features at various positions on a wafer. Therefore, the resolution capability of a lithography process may be improved by reducing temperature variations across the bake plate of a PEB process module.

There are several disadvantages, however, in using currently available methods to improve the resolution capability of lithography processes. For example, currently available methods may not account for degradation in the uniformity of a critical parameter over time. For a PEB module, thermal relaxation of heating elements, contamination, or other performance variations may adversely affect the resolution capability of a lithography process to various degrees over time. As such, monitoring and controlling time-dependent variations in the critical parameters may maintain and improve the performance characteristics of a lithography process. In addition, integrated control mechanisms that may currently be used to monitor variations in the temperature of the PEB module may control and alter the process at the wafer level. Therefore, all positions, or fields, on the wafer are affected equally, and improvements are made for an average performance across the wafer. In this manner, systematic variations in the resolution capability from field to field across a wafer may not be monitored or altered, which may have an adverse affect on the overall performance characteristics of the lithography process.

Lithography track manufacturers have developed stable, well controlled, PEB plates. Some PEB plates include multiple heating elements such that the plate temperature (T) can be varied across the surface of the plate to compensate for across plate non-uniformity (systematic errors). However, by design, it is difficult to adjust the T across the plate (due to, for example, thermal mass, design, and the inability to correlate changes in T to end results (e.g., dimensions of patterned features) in the resist).

Plate T inputs are generally selected based on characterization experiments using either product wafers or specific wafers that include T sensors, and the settings are fixed for a given product and layer.

Existing methods used to determine temperature set points do not take into account and therefore cannot compensate for the following phenomena: drifts in each plate (e.g., time variation in the temperature set point), interaction between plate and wafer that results in a local thermal history on the wafer that is different than that of the plate, and thermal history modifications that are due to prior steps (e.g., time between exposure of a wafer and the PEB step). In accordance with the plate design, currently available track configurations enable only the monitoring of the local thermal history of the plate and do not enable the monitoring of the wafer parameters (either T history or latent image critical dimension (CD) across the wafer). Therefore, although modifying the thermal history of the whole wafer by adjusting the bake time is possible, such modifications cannot improve across wafer (x-wafer) uniformity and will even degrade wafer mean uniformity (e.g., due to lack of correlation to actual wafer parameters).

In the literature, one can find several proposals for enabling wafer based control. For example, Sturtevant (1995, SPIE 2196) and U.S. Pat. No. 5,516,608 to Hobbs et al., which are incorporated by reference as if fully set forth herein, propose an apparatus (that is configured for 1st order diffraction measurements using a circular light emitting diode (LED) source) configured to measure the latent image (averaged over a relatively large area) of a memory wafer and to adjust bake time to compensate for the latent image signal. However, the level of control that can be achieved using this apparatus is limited because the apparatus is configured such that only one location on the wafer can be measured (i.e., the apparatus cannot measure x-wafer non uniformity) and uses a coherent, single wavelength source, which is sensitive to film stack variations and is, therefore, not a reliable measurement of the latent image.

Prins et al. (1996, SPIE 2725), which is incorporated by reference as if fully set forth herein, propose measuring the reflected light instead of the 1st order diffracted light, but note that the reflected light is less sensitive to the latent image. Additional examples of currently used methods and systems are described by Friedberg et al. (SPIE 2004) and Smith et al. (2001, SPIE 4345), which are incorporated by reference as if fully set forth herein.

Accordingly, it may be advantageous to develop methods and systems for controlling variation in dimensions of patterned features across a wafer by compensating for non-time varying spatial variation in a temperature to which the wafer is exposed during a PEB step of a lithography process and one or more of time varying spatial variation in the temperature, variation in energy transfer to the wafer, and variation in time between an exposure step of the lithography process and initiation of the PEB step.

### SUMMARY OF THE INVENTION

The following description of various embodiments of methods and systems is not to be construed in any way as limiting the subject matter of the appended claims.

One embodiment relates to a method for controlling variation in dimensions of patterned features across a wafer. The method includes measuring a characteristic of a latent image formed in a resist at more than one location across a wafer during a lithography process. The method also includes altering a parameter of the lithography process in response to the characteristic to reduce variation in dimensions of patterned features formed across the wafer by the lithography process. Altering the parameter compensates for non-time varying spatial variation in a temperature to which the wafer is exposed during a post exposure bake (PEB) step of the lithography process and an additional variation in the PEB step.

In one embodiment, the additional variation includes time varying spatial variation in the temperature. In another embodiment, the additional variation includes variation in energy transfer to the wafer. In a further embodiment, the additional variation includes variation in time between an exposure step of the lithography process and initiation of the PEB step.

In one embodiment, the parameter includes the temperature to which different portions of the wafer are exposed during the PEB step. In another embodiment, the parameter includes a temperature to which different portions of the wafer are exposed during a bake step performed during the lithography process after the PEB step. In a further embodiment, the parameter includes a parameter of a develop step performed during the lithography process after the PEB step.

In some embodiments, measuring the characteristic includes optically measuring the characteristic of the latent image. In another embodiment, measuring the characteristic includes optically measuring the characteristic of the latent image at more than one wavelength. In a further embodiment, measuring the characteristic includes optically measuring the characteristic of the latent image across a spectrum of wavelengths. In an additional embodiment, measuring the characteristic includes optically forming an image of the latent image and determining the characteristic from the image. In other embodiments, measuring the characteristic includes measuring byproducts of the PEB step and determining the characteristic from the byproducts.

In some embodiments, measuring the characteristic includes measuring the characteristic of the latent image at the more than one location sequentially. In a different embodiment, measuring the characteristic includes measuring the characteristic of the latent image at the more than one location simultaneously. In a further embodiment, measuring the characteristic includes measuring the characteristic of the latent image during the PEB step. Each of the embodiments of the method described above may include any other step(s) described herein.

Another embodiment relates to a system configured to control variation in dimensions of patterned features across a wafer. The system includes a device configured to measure a characteristic of a latent image formed in a resist at more than one location across a wafer during a lithography process. The system also includes a control subsystem configured to alter a parameter of the lithography process in response to the characteristic to reduce variation in dimensions of patterned features formed across the wafer by the lithography process. Altering the parameter compensates for non-time varying spatial variation in a temperature to which the wafer is exposed during a PEB step of the lithography process and an additional variation in the PEB step.

In one embodiment, the additional variation includes time varying spatial variation in the temperature. In another embodiment, the additional variation includes variation in energy transfer to the wafer. In a further embodiment, the additional variation includes variation in time between an exposure step of the lithography process and initiation of the PEB step.

In one embodiment, the parameter includes the temperature to which different portions of the wafer are exposed during the PEB step. In another embodiment, the parameter includes a temperature to which different portions of the wafer are exposed during a bake step performed during the lithography process after the PEB step. In a further embodiment, the parameter includes a parameter of a develop step performed during the lithography process after the PEB step.

In one embodiment, the device includes an optical device. In another embodiment, the device is configured to measure the characteristic of the latent image at more than one wavelength. In a further embodiment, the device is configured to measure the characteristic of the latent image across a spectrum of wavelengths. In an additional embodiment, the device is configured to optically form an image of the latent image and to determine the characteristic from the image. In other embodiments, the device is configured to measure byproducts of the PEB step and to determine the characteristic of the latent image from the byproducts.

In one embodiment, the device is configured to measure the characteristic of the latent image at the more than one location sequentially. In a different embodiment, the device is configured to measure the characteristic of the latent image at the more than one location simultaneously. In a further embodiment, the device is configured to measure the characteristic of the latent image during the PEB step. Each of the embodiments of the system described above may be further configured as described herein.

### BRIEF DESCRIPTION OF THE DRAWINGS

Further advantages of the present invention may become apparent to those skilled in the art with the benefit of the following detailed description of the preferred embodiments and upon reference to the accompanying drawings in which:

FIG. 1 depicts a flow chart illustrating a method for evaluating and controlling a lithography process;

FIG. 2 depicts a plan view of a bake plate of a post exposure bake process module having a number of discrete secondary heating elements in addition to an overall primary heating element;

FIG. 3 depicts a block diagram of a system configured to evaluate and control a lithography process;

FIG. 4 is a side view block diagram showing a measurement device that may be used in the embodiments described herein;

FIG. 5 is a schematic diagram of a measurement device that may be used in the embodiments described herein;

FIG. 6 is a schematic diagram illustrating a cross-sectional view of one embodiment of a system configured to control variation in dimensions of patterned features across a wafer;

FIG. 7 is a schematic diagram illustrating a cross-sectional view of one example of a latent image formed in a resist on a wafer;

FIGS. 8-10 are schematic diagrams illustrating a cross-sectional view of various embodiments of a device configured to measure a characteristic of a latent image formed in a resist at more than one location across a wafer during a lithography process;

FIG. 11 is a schematic diagram illustrating a top view of one embodiment of a bake plate configured such that a parameter of the bake plate can be altered according to embodiments described herein; and

FIG. 12 is a schematic diagram illustrating a cross-sectional view of one example of patterned features formed across a wafer.

While the invention is susceptible to various modifications and alternative forms, specific embodiments thereof are shown by way of example in the drawings and may herein be described in detail. The drawings may not be to scale. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE PREFERRED EMBODIMENTS

As used herein, the term “wafer” generally refers to substrates formed of a semiconductor or non-semiconductor material. Examples of such a semiconductor or non-semiconductor material include, but are not limited to, monocrystalline silicon, gallium arsenide, and indium phosphide. Such substrates may be commonly found and/or processed in semiconductor fabrication facilities.

A wafer may include one or more layers formed upon a substrate. For example, such layers may include, but are not limited to, a resist, a dielectric material, and a conductive material. The terms “resist” and “photoresist” are used interchangeably herein. Many different types of such layers are known in the art, and the term wafer as used herein is intended to encompass a wafer including all types of such layers.

One or more layers formed on a wafer may be patterned. For example, a wafer may include a plurality of dies, each having repeatable patterned features. Formation and processing of such layers of material may ultimately result in completed devices. Many different types of devices may be formed on a wafer, and the term wafer as used herein is intended to encompass a wafer on which any type of device known in the art is being fabricated.

Turning now to the drawings, it is noted that the figures are not drawn to scale. In particular, the scale of some of the elements of the figures is greatly exaggerated to emphasize characteristics of the elements. It is also noted that the figures are not drawn to the same scale. Elements shown in more than one figure that may be similarly configured have been indicated using the same reference numerals.

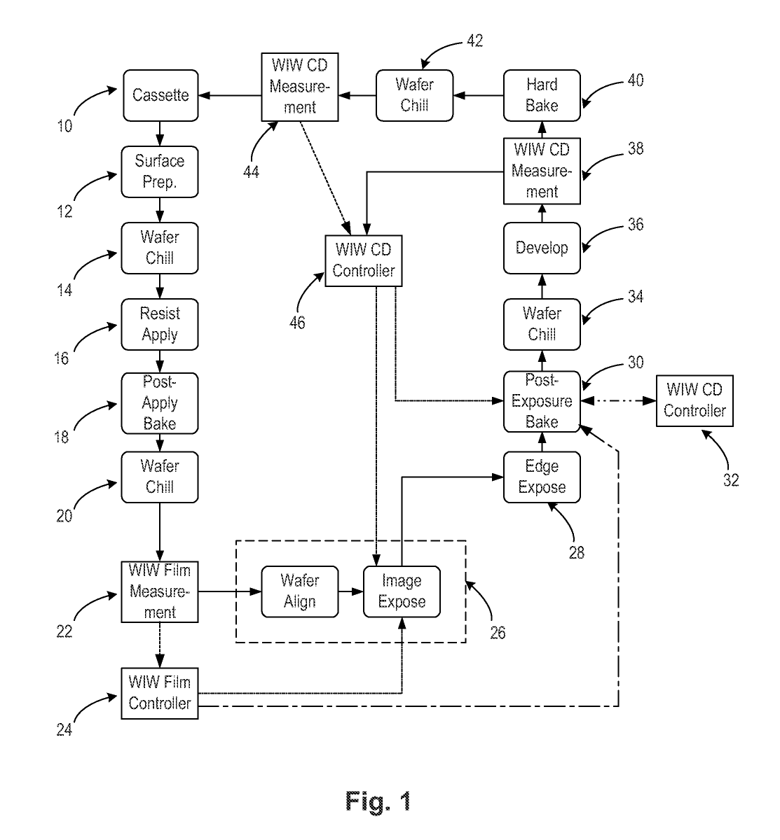

FIG. 1 illustrates an embodiment of a method to evaluate and control performance characteristics of a lithography process. For example, the method may be used to reduce, and even to minimize, within wafer (“WIW”) variability of critical metrics of the lithography process. Critical metrics of a lithography process may include, but are not limited to, critical dimensions of features formed by the lithography process and overlay. Critical dimensions of features formed during the lithography process may include, for example, a width, a height, and a sidewall profile of the features. A sidewall profile of a feature may be described, for example, by a sidewall angle of the feature with respect to an upper surface of a wafer, a roughness of the sidewall of the feature, and other physical characteristics of the feature. Overlay generally refers to a lateral position of a feature on one level of a wafer with respect to a lateral position of a feature on another level of the wafer. The lithography process may include optical lithography, e-beam lithography, or x-ray lithography.

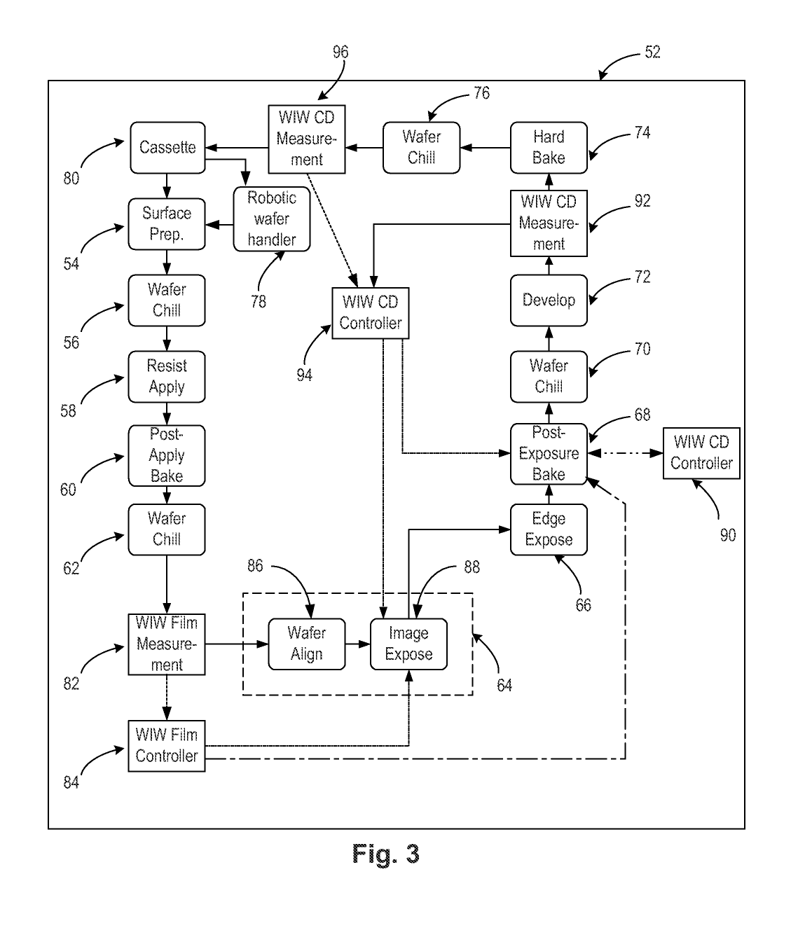

A lithography cluster tool, or a lithography track, (e.g., lithography cluster tool 52 shown in FIG. 3) may include a set of process modules (e.g., surface preparation chamber 54, wafer chill module 56, resist apply process module 58, post apply bake module 60, wafer chill module 62, exposure process module 64, edge exposure module 66, post exposure bake (PEB) module 68, wafer chill module 70, develop module 72, hard bake module 74, and wafer chill module 76 shown in FIG. 3). An example of a lithography cluster tool is illustrated in U.S. Pat. No. 5,968,691 to Yoshioka et al., and is incorporated by reference as if fully set forth herein. The lithography cluster tool may be coupled to an exposure tool. A first portion of the process modules may be configured to perform at least one step of the lithography process prior to exposure of the resist. A second portion of the process modules may be configured to perform process steps of the lithography process subsequent to exposure of the resist. The lithography cluster tool may also include at least one robotic wafer handler (e.g., robotic wafer handler 78 shown in FIG. 3). The robotic wafer handler may move wafers from module to module. The robotic wafer handler may also be used to move wafers from the lithography cluster tool to the exposure tool.

As shown in step 10, the robotic wafer handler may pick up a wafer from a cassette (e.g., cassette 80 shown in FIG. 3), which may be loaded into the lithography cluster tool by an operator. The cassette may contain a number of wafers which may be processed during the lithography process. The wafers may be bare silicon wafers. Alternatively, the wafers may have been processed prior to the lithography process. For example, topographical features may have been formed on the wafers. The topographical features may include trenches, vias, lines, etc. In addition, one or more layers of a material such as a dielectric material may have been formed on the wafers prior to the lithography process.

The wafer may be placed in a process module such as a surface preparation chamber, as shown in step 12. The surface preparation chamber may be configured to form a layer of an adhesion promoting chemical such as hexamethyldisilazane (HMDS) onto the surface of the wafer. HMDS may be deposited at a temperature of approximately 80° C. to approximately 180° C. Therefore, after the surface preparation process, the robotic wafer handler may remove the wafer from the surface preparation chamber and may place the wafer into a chill module, as shown in step 14. As such, a wafer may be lowered to a temperature suitable for subsequent processing (e.g., approximately 20° C. to approximately 25° C.).

In an additional embodiment, an anti-reflective coating may also be formed on the surface of the wafer. The anti-reflective coating may be formed on the wafer, for example, by spin coating followed by a post apply bake process. Since a post apply bake process for an anti-reflective coating generally involves heating a coated wafer to a temperature of approximately 175° C. to approximately 230° C., a chill process may also be performed subsequent to the post apply bake process.

A resist may be formed upon the wafer, as shown in step 16. For example, the wafer may be placed into a resist apply process module. A resist may be automatically dispensed onto an upper surface of the wafer. The resist may be uniformly distributed across the wafer by spinning the wafer at a high rate of speed such as about 2000 rpm to about 4000 rpm. The spinning process may adequately dry the resist such that the wafer may be removed from the resist apply module without affecting the coated resist. As shown in step 18, the resist-coated wafer may be heated in a post apply bake process. The post apply bake process may include heating the resist-coated wafer at a temperature of approximately 90° C. to approximately 140° C. The post apply bake process may be used to drive excess solvent out of the resist and to alter a property of an upper surface of the resist such as surface tension. Subsequent to the post apply bake process, the wafer may be chilled at a temperature of approximately 20° C. to approximately 25° C., as shown in step 20.

The method may also include measuring a property of the resist formed upon the wafer subsequent to chilling. As shown in step 22, for example, the wafer may be moved to a measurement device, or a within wafer film measurement device (e.g., within wafer film measurement device 82 shown in FIG. 3), subsequent to chilling after the post apply bake step. Alternatively, the wafer may remain in the chill module during measurement if, for example, the measurement device is coupled to the chill module. The measurement device may be any device configured to use an optical technique to measure at least one property of the resist. The measurement device may also be configured to measure at least one property of the resist at more than one position on the wafer. The optical technique may include, but is not limited to, scatterometry, interferometry, reflectometry, spectroscopic ellipsometry or spectroscopic reflectometry. Additionally, other optical measurement devices may also be used to measure a property of the resist. Examples of measurement devices which may be used are illustrated in U.S. Pat. No. 4,999,014 to Gold et al., U.S. Pat. No. 5,042,951 to Gold et al., U.S. Pat. No. 5,412,473 to Rosencwaig et al., U.S. Pat. No. 5,516,608 to Hobbs et al., U.S. Pat. No. 5,581,350 to Chen et al., U.S. Pat. No. 5,596,406 to Rosencwaig et al., U.S. Pat. No. 5,596,411 to Fanton et al., U.S. Pat. No. 5,608,526 to Piwonka-Corle et al., U.S. Pat. No. 5,747,813 to Norton et al., U.S. Pat. No. 5,771,094 to Carter et al., U.S. Pat. No. 5,798,837 to Aspnes et al., U.S. Pat. No. 5,859,424 to Norton et al., U.S. Pat. No. 5,877,859 to Aspnes et al., U.S. Pat. No. 5,889,593 to Bareket et al., U.S. Pat. No. 5,900,939 to Aspnes et al., U.S. Pat. No. 5,910,842 to Piwonka-Corle et al., U.S. Pat. No. 5,917,588 to Addiego, U.S. Pat. No. 5,917,594 to Norton, U.S. Pat. No. 5,973,787 to Aspnes et al., and U.S. Pat. No. 5,991,699 to Kulkarni, et al. and are incorporated by reference as if fully set forth herein. Additional examples of measurement devices are illustrated in PCT Publication No. WO 99/02970 to Rosencwaig et al. and PCT Application No. WO 99/45340 to Xu et al., and are incorporated by reference as if fully set forth herein.

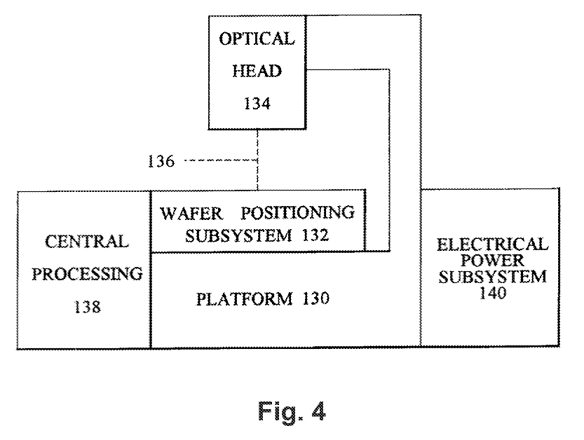

With reference to FIG. 4, a practical apparatus for semiconductor wafer metrology integrates an angle-dependent reflectometer within a machine that automates the measurement process. The apparatus can repeat the desired measurement or measurements at many pre-programmed locations on a wafer, and on many wafers, at a high rate with minimal intervention on the part of a human operator. The apparatus includes a platform 130, which is a stable table that provides isolation from floor vibrations by means of springs or pneumatic isolators. The platform 130 holds a wafer positioning subsystem 132 and an optical head 134 containing the reflectometer. Relative motion between those two elements 132 and 134 is held by the platform 130 during measurements to less than 2 to 5 micrometers. The platform 130 can also include means for moving the optical head 134 up and down relative to the wafer positioning assembly 132 to allow for unobstructed loading or unloading of a wafer by a wafer handler and also to provide coarse focusing in order to accommodate wafers of various thicknesses.

The apparatus' wafer positioning subsystem 132 includes or cooperates with wafer handling equipment for loading and unloading wafers onto the machine. The wafer handling equipment includes one or more wafer storage cassettes and an autoloader assembly that moves wafers between the storage cassettes and a stage. The autoloader usually forms an integral part of the overall instrument. The cassettes are typically provided separately. The wafer positioning subsystem 132 further includes a stage assembly with a vacuum chuck that holds a wafer securely and a combination of motors and slides that produce precise motion of the stage in at least two, and preferably three, axes. Fine z-axis motion (up and down), if not provided by the stage, can be provided by the optical head 134. The stage may also provide for rotational motion of the wafer.

Wafer positioning is the result of cooperation between the wafer positioning subsystem 132, a wafer alignment sensor in the optical head 134, and motion control provided by a central processing system 138. The alignment sensor is a low magnification (about 1× to 6×) camera that images a small illuminated area of a semiconductor die on the wafer. A motion control processor in the central processing system 138 receives image data from the alignment sensor, employs pattern recognition algorithms to identify unique alignment marks or recognizable pattern features on the wafer, and then controls the motion motors of the stage to automatically position the wafer at an initial point and align it with the axes of motion. The wafer can then be navigated to designated measurement positions for that wafer. A template matching technique like that described by Ramesh Jain, et al. in the book Machine Vision, published by McGraw-Hill Inc. (1995), section 15.6.1, pages 482-483, can be used to recognize a wafer's alignment mark. Measurement points relative to an initial wafer position can be designated by a user for a particular class of wafers to be inspected.

The optical head 134 is in optical communication 136 with the wafer on the positioning subsystem's stage. In addition, it includes the wafer alignment sensor (camera) that aids the wafer positioning subsystem 132. Further, the optical head 134 includes a focus sensor that enables automatic focusing. One commonly used focus sensor uses a light source that is focused on the wafer surface at an angle. The reflected light is detected by a bi-cell detector. As the focus varies, the detected beam will translate across the bi-cell. This type of autofocus system is described by D. H. Kim et al. in Proceedings SPIE, vol. 2726, pages 876-885 (1996). The three optical head elements, reflectometer, alignment sensor and autofocus sensor, are not optically integrated, but are physically mounted together within a single unit and have a common focus condition. While the alignment sensor normally images a slightly different location than the spot illuminated by the reflectometer, the lateral displacement is fixed and can be taken into account when positioning the wafer for measurement. Likewise, even if the autofocus sensor were to use a slightly different location on the wafer for determining the focus condition, the wafer is sufficiently flat that focus would be within the required focus tolerance for the reflectometer.

An electrical power subsystem 140 includes one or more power supplies and distribution cables to provide AC and DC power to the electronic components and motion motors of the apparatus.

The central processing system 138 includes one or more computer processors for digital motion control of the wafer positioning system 132 stage and of the optical head 134 and for data acquisition and analysis. For example, there may be several processors which are each dedicated to a particular function and a main or host processor for coordinating the separate processors. Moreover, there may be one or more data ports and a network interface processor for possible interaction via a network with a factory computer. The central processing system 132 also includes memory for storing designated measurement locations as well as actual measurement data and the analysis results. The system shown in FIG. 4 may be further configured as described in U.S. Pat. No. 5,889,593 to Bareket, which is incorporated by reference above.

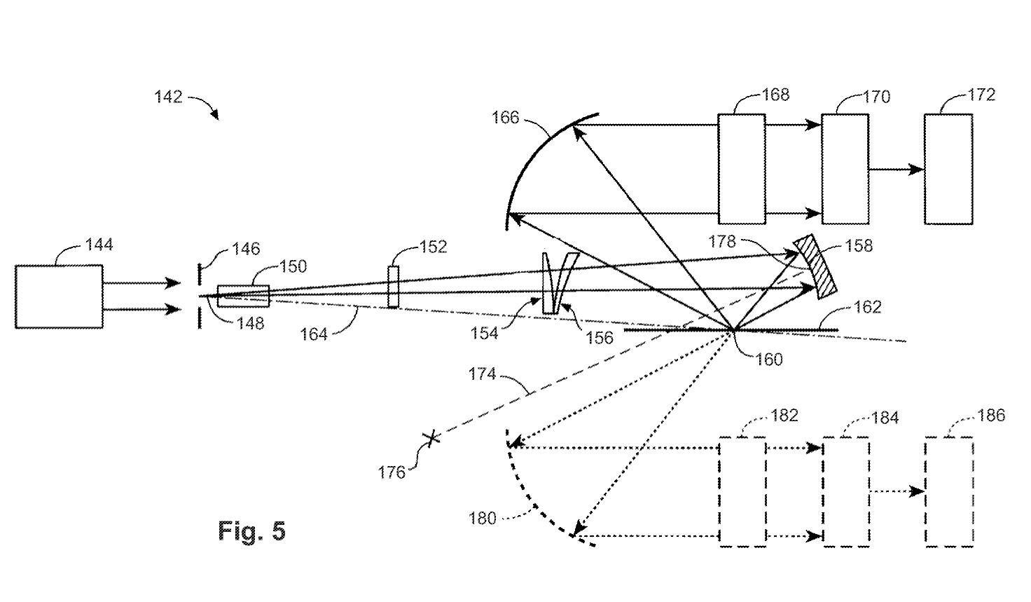

FIG. 5 illustrates a measurement device that may be used in embodiments described herein. In reference to system 142 of FIG. 5, a broadband radiation source (preferably a xenon arc lamp) 144 supplies radiation through an aperture 146 along an optical path 148 to a polarizer 150. Polarizer 150 polarizes the radiation and the polarized radiation is passed through an apodizer 152 which also acts as an aperture stop for the system 142. The beam from apodizer 152 is passed through lens 154 and 156 to a spherical mirror 158 which focuses the radiation onto a small spot 160 on the surface of sample 162. An image of the aperture is thus focused onto an image plane at the spot 160, and the dotted line 164 connecting the aperture and the spot is the optical axis of system 142. The radiation reflected from sample 162 is collected by a collection mirror 166 which focuses the collected light to an analyzer 168 and a spectrometer 170 with its associated aperture (not shown). The output of the spectrometer is analyzed by a computer 172 to determine the change in amplitude and phase of polarization caused by interaction of the sampling beam with the sample.

By replacing an ellipsoidal mirror of U.S. Pat. No. 5,608,526 with a spherical mirror as in FIG. 5, the limiting factor of errors produced by diamond turning is eliminated and the minimum box size within which accurate ellipsometric measurements can be made is no longer so limited. The box size achieved in this invention can be 40 by 40 microns or smaller. In the preferred or other embodiments, a polarizer and an analyzer can include any element that modifies the polarization of radiation, such as a linear polarizer and a wave plate or an acousto-optic modulator. The axis 174 of the mirror may be defined with respect to its center of curvature 176 and center 178 of the illuminated area on the mirror in the preferred embodiment as shown in FIG. 5.

Instead of collecting and detecting radiation that is reflected by a sample 162, where the sample transmits radiation, it is also possible to detect radiation that is transmitted through the sample, such as by means of mirror 180, which focuses the collected radiation to analyzer 182 and spectrometer 184 and computer 186, shown in dotted lines in FIG. 5, and to thereby determine the change in amplitude and phase of polarization caused by interaction of the sampling beam with the sample. In still other variations, it may be possible to collect radiation that is scattered by or through the sample to determine the change in amplitude and phase of polarization caused by interaction of the sampling beam with the sample. The system shown in FIG. 5 may be further configured as described in U.S. Pat. No. 5,917,594 to Norton, which is incorporated by reference above.

The measurement device may measure at least one property of the resist. In addition, the measurement device may measure several properties of the resist substantially simultaneously. A property of the resist measured subsequent to a post apply bake process may include, but is not limited to, a thickness, an index of refraction, or an extinction coefficient of the resist. The measured property may be sent to a controller computer, or a within wafer film controller (e.g., within wafer film controller 84 shown in FIG. 3), as shown in step 24 of FIG. 1. The controller computer may be coupled to the measurement device. The controller computer may determine a parameter of a process step of the lithography process in response to the measured property of the resist. For example, the controller computer may determine a parameter of a process step as a function of the resist using an experimentally determined or numerically simulated relationship. The controller computer may also be coupled to at least one process module of the lithography cluster tool. In this manner, the controller computer may be configured to alter a parameter of a process module of a lithography cluster tool. Therefore, the controller computer may control the operation of any of the process modules included in the lithography cluster tool. Alternatively, a parameter of a process module may be altered manually by an operator in response to output from the measurement device or the controller computer.

In an embodiment, a feedforward control technique may be used to alter a parameter of a process module. For example, an operator or a controller computer may determine at least one parameter of a process module that may be used to perform an additional lithography process step on the measured resist. Additional lithography process steps may include exposure and PEB. In this manner, the property of the resist may be used to alter a parameter of a process module configured to perform an exposure step or a PEB step. For example, a thickness, an index of refraction, and/or an extinction coefficient of the resist measured subsequent to the chilling process may be used to determine an exposure dose of an exposure process or a temperature of the PEB process. An operator or the controller computer may alter at least one parameter of the exposure process module or the PEB process module in response to the determined exposure dose or temperature, respectively.

In addition, because at least one property of the resist may be measured at various positions across the wafer, at least one parameter may be determined for each of the various positions. As such, a parameter of a process module may also be altered, as described above, independently from field to field on the wafer. For example, process conditions such as exposure dose and/or PEB temperature may vary across the wafer in subsequent processes in response to variations in at least one measured property from field to field across the wafer. In this manner, critical metrics of the lithography process may be substantially uniform across the wafer.

In an additional embodiment, a feedback control technique may be used to alter a parameter of a process module. In this manner, a parameter of at least one process module that may have been used to form the resist may be altered prior to or during processes to form resist on additional wafers. Such a parameter may be determined in response to at least the one measured property of the resist as described above. For example, the property of the resist may be used to alter a parameter of the resist apply process module or the post apply bake process module prior to and/or during processing of additional wafers.

As shown in step 26, the wafer may be transferred to an exposure process module. The exposure process module may perform a number of operations that may include, but are not limited to, aligning a wafer (e.g., using wafer align module 86 shown in FIG. 3) and exposing the resist in a predetermined pattern (e.g., using image expose module 88 shown in FIG. 3). For example, the exposure process module may include any stepper or scanner known in the art. Exposing the resist may also include exposing the resist to a specific intensity of light, or an exposure dose, and a specific focus condition. Many exposure process modules may be configured such that the exposure dose and focus conditions of the expose process may be varied across the wafer, for example, from field to field. The exposure dose and focus conditions may be determined and/or altered as described herein using a feedback or feedforward control technique.

As shown in step 28, an optional process step in the lithography process may include an edge exposure step. The edge exposure step may include exposing resist disposed proximate an outer edge of the wafer to a light source to remove the resist at the outer edge of the wafer. Such removal of the resist at the outer edge of a wafer may reduce contamination of process chambers and devices used in subsequent processes.

As shown in step 30, the wafer may be subjected to a PEB process step. The PEB process may be used to drive a chemical reaction in exposed portions of the resist such that portions of the resist may be removed in subsequent processing. As such, the performance of the PEB process may be critical to the performance of the lithography process. The PEB process may include heating the wafer to a temperature of approximately 90° C. to approximately 150° C. As shown in step 32, a measurement device, or a within wafer critical dimension measurement device (e.g., within wafer CD controller 90 shown in FIG. 3), may be coupled to the PEB process module. In this manner, a property of the resist may be measured during the PEB process. The measurement device may use an optical technique to measure a property of the resist such as thickness, linewidth of a latent image, height of a latent image, index of refraction, or extinction coefficient. The measurement device may be configured to use a technique such as scatterometry, interferometry, reflectometry, spectroscopic ellipsometry, and spectroscopic reflectometry. Additional examples of measurement devices may include any of the measurement devices as described herein. Therefore, the measured property of the resist may be used to evaluate and control the PEB process using an in situ control technique. For example, the measurement device may measure a property of the resist during the PEB process, and a parameter of the PEB process module may be altered in response to the measured property during the process.

In addition, the measurement device may be used to measure a property of the resist at various times during a PEB process. As such, the measurement device may monitor variations in at least one property of the resist over time. In this manner, a signature characteristic of an endpoint of the PEB process may be determined, and at which time, the process may be ended. Monitoring variations in at least one property of the resist during the PEB process may also be enhanced by measuring at least one property of the resist at multiple positions on the wafer.

The measurement device may be configured to measure a property of the resist at multiple positions within a field and at multiple positions within at least two fields on the wafer during the PEB process. In this manner, at least one parameter of the process module may be determined at various positions across the wafer. As such, a parameter of the PEB module may be altered independently as described above from field to field on the wafer. For example, a temperature of a bake plate of the PEB process module may vary across the bake plate during the PEB process in response to variations in at least one measurement property of the resist from field to field across the wafer. Therefore, within wafer variations of critical parameters may be reduced, or even minimized.

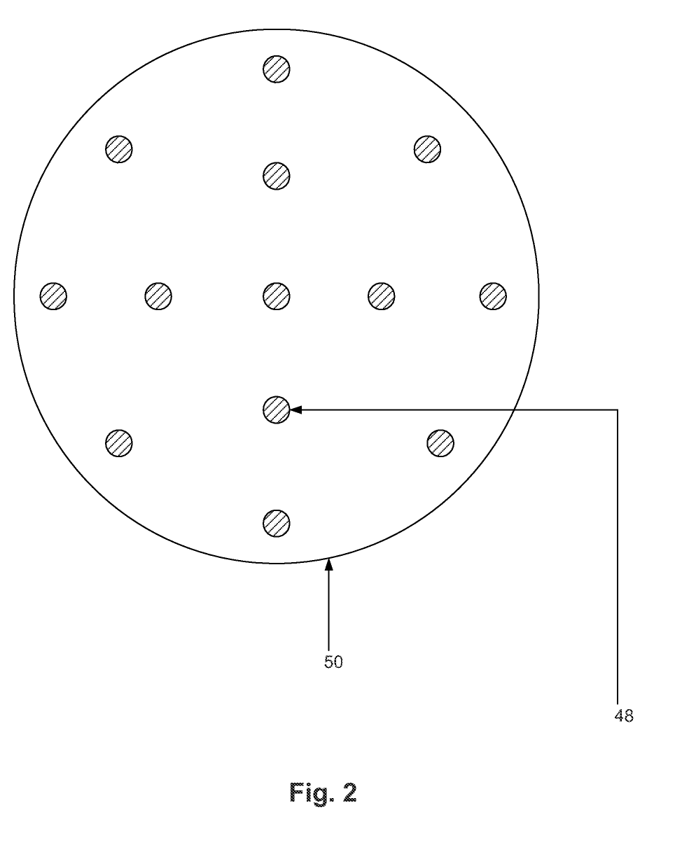

As shown in FIG. 2, a temperature of the PEB plate may be altered across the bake plate by using a number of discrete secondary heating elements 48 disposed within primary heating element 50. Secondary heating elements 48 and primary heating element 50 may include resistive heating elements or any other heat source known in the art. Secondary heating elements 48 may be independently controlled, for example, by altering an electrical current supplied to each of the secondary heating elements to alter a temperature profile of primary heating element 50. As such, a temperature profile across a wafer during a PEB process may be altered such that individual fields on a wafer may be heated at substantially the same temperature or at individually determined temperatures. In this manner, a uniformity of critical metrics of a lithography process across a wafer may be increased.

Referring to FIG. 1 again, as shown in step 34, subsequent to the PEB process, the wafer may be chilled. Subsequent to chilling, the wafer may be moved to a measurement device. Alternatively, the wafer may remain in the chill module during measurement if for example, the measurement device is coupled to the chill module. The measurement device may be configured as any measurement device as described herein. The measurement device may measure at least one property of the resist. In addition, the measurement device may measure several properties of the resist substantially simultaneously. A property of the resist measured subsequent to or during the chill process may include, but is not limited to, a thickness, a linewidth of a latent image, a height of a latent image, an index of refraction, or an extinction coefficient. The measured property of the resist may be used to alter a parameter of a process module of the lithography cluster tool using a feedback control technique or a feedforward control technique. For example, the measured property of the resist may be used to alter an exposure dose or a PEB temperature using a feedback control technique or to alter a develop time using a feedforward control technique.

The measurement device may be configured to measure a property of the resist at multiple positions within a field and at multiple positions within at least two fields on the wafer subsequent to or during the chill process. In this manner, at least one parameter of a process module of a lithography cluster tool may be determined at various positions across the wafer. As such, a parameter of an exposure process module, a PEB process module, or a develop process module may be altered independently as described above from field to field on the wafer. For example, a temperature of a bake plate of the PEB process module may vary across the bake plate in response to variations in at least one measurement property of the resist from field to field across the wafer. As described above, therefore, within wafer variations of critical parameters may be reduced, or even minimized.

As shown in step 36, subsequent to the PEB process, the wafer may be subjected to a develop process step. The develop process step may be configured to remove a portion of the resist. For example, a develop process may include dispensing an aqueous developer solution on a wafer subsequent to a PEB process and rinsing the wafer with de-ionized water. Resist remaining after the develop process step may define a pattern formed in the original resist layer. The formed pattern may include an arrangement of lines, spaces, trenches, and/or vias. Subsequent to the develop process, as shown in step 38, a measurement device, or a within wafer critical dimension measurement device (e.g., within wafer critical dimension measurement device 92 shown in FIG. 3), may be used to measure a property of the resist such as, but not limited to, a thickness, an index of refraction, or an extinction coefficient of the remaining resist, a width, a height, or a sidewall profile of a feature, or overlay. The measured property may be sent to a controller computer, or within wafer critical metric controller (e.g., within wafer critical dimension controller 94 shown in FIG. 3), as shown in step 46 of FIG. 1.

A parameter of a process module involved in the lithography process may be altered in response to the measured property using a feedback control technique. For example, the altered parameter of the process module may be a function of the measured property of the resist. The feedback control technique may include, for example, measuring a linewidth of features formed in the resist subsequent to the develop process step and altering a parameter of an expose process module or a PEB process module, which may be used to fabricate additional wafers. In addition, a linewidth of features formed in the resist may be measured at various positions across the wafer subsequent to the develop process step. In this manner, parameters of an expose process module may be altered at the field level in response to the measured properties of the resist by altering parameters of the expose process step such as the exposure dose and the exposure focus conditions at each field. As such, the controller computer may provide a two-dimensional array of exposure doses and/or exposure focus conditions to the exposure process module in response to the measured property of the resist. Therefore, variations in wafer critical metrics of the lithography process may be reduced, or even minimized.

As shown in step 40, subsequent to measuring a property of the resist, a hard bake, or post develop bake, process step may be performed. The hard bake process may be used to drive contaminants and any excess water from the resist. Therefore, the hard bake process may include heating the wafer at a temperature of approximately 90° C. to approximately 130° C. As shown in step 42, the temperature of the wafer may then be reduced by using a wafer chill process. Subsequent to the wafer chill process of step 42, an additional measurement of at least one property of the resist may be performed as described herein, as shown in step 44. The measurement device (e.g., within wafer critical dimension measurement device 96 shown in FIG. 3) may be configured as described in any of the above embodiments. This measurement may also be used to alter a parameter of a process module using a feedback control technique as described herein. For example, at least one measured property of a resist may be sent to a controller computer, or a within wafer critical dimension controller, as shown in step 46.

It is to be understood that all of the measurements described above may be used to alter a parameter of a lithography process module using a feedback, a feedforward, or an in situ process control technique. In addition, within wafer variations of critical metrics of a lithography process may be further reduced by using a combination of the above techniques. The method may also include measurements at additional points in a lithography process such as measuring at least one property of an anti-reflective coating subsequent to forming the anti-reflective coating on a wafer. The property of the anti-reflective coating may be used to alter a parameter of a process module using a feedback control technique, a feedforward control technique, or an in situ control technique as described herein.

In an additional embodiment, a system configured to evaluate and control a lithography process may include at least one measurement device and at least one process module. The system may be configured to reduce, and even to minimize, within wafer variability of at least one critical metric of the lithography process. Critical metrics of a lithography process include, but are not limited to, critical dimensions of features formed by the lithography process and overlay as described above.

A measurement device may be configured to measure at least one property of a resist disposed upon a wafer during the lithography process. As shown in FIG. 1, for example, a measurement device may include within wafer film measurement device 22, within wafer critical dimension measurement device 32, within wafer critical dimension measurement device 38, and/or within wafer critical dimension measurement device 44. Such measurement devices may be configured as described herein. In addition, the system may include additional measurement devices as described herein. The measurement device may be configured to measure the property of the resist during any of the process steps as described above or subsequent to any of the process steps as described above.

In an embodiment, therefore, the measurement device may be coupled to at least one of the process modules such that the measurement device may perform an in situ measurement of a resist. Alternatively, the measurement device may be disposed within a lithography cluster tool such that the measurement device may perform a measurement of a resist between two process steps. In this manner, a method as described herein may have a quicker turn around time than conventional lithography process control methods. As described herein, at least the one measured property may include a thickness, an index of refraction, an extinction coefficient, a linewidth of a latent image, a height of a latent image, a width of a feature, a height of a feature, a sidewall profile of a feature, overlay, or any combination thereof. At least the one measurement device may also be configured to measure at least the one property of the resist at various locations across the wafer. For example, a thickness of the resist may be measured at various positions or fields across the wafer. In addition, a property of the resist may be measured at various positions within a field of the wafer or at various positions within several fields of the wafer.

A process module may be configured to perform a step of the lithography process. As shown in FIG. 1, for example, such process modules may include, but are not limited to, surface preparation chamber 12, resist apply process module 16, post apply bake process module 18, exposure process module 26, PEB process module 30, develop process module 36, and hard bake process module 40. At least one parameter of the process module may be altered in response to at least the one measured property such that within wafer variation of the critical metric can be reduced, or even minimized. For example, at least one parameter of a process module may be altered using a feedback control technique, a feedforward control technique, an in situ control technique, or any combination thereof.

In addition, at least the one parameter of the process module may be altered such that a first portion of the wafer may be processed with a first set of process conditions during a step of the lithography process and such that a second portion of the wafer may be processed with a second set of process conditions during the step. For example, each portion of the wafer may be a field of the wafer. In this manner, each field of the wafer may be subjected to different process conditions such as, but not limited to, exposure dose and focus conditions and PEB temperatures. As such, because each field of a wafer may be subjected to process conditions that may vary depending upon a measured property of a resist formed upon the wafer, within wafer variations in critical metrics of the lithography process may be substantially reduced, or even minimized.

The system may also include a controller computer coupled to at least one measurement device and to at least one process module. As shown in FIG. 1, for example, a controller computer may include within wafer film controller 24 and within wafer critical dimension controller 46. The controller computer may include any appropriate controller device known in the art. The controller computer may be configured to receive at least one measured property of the resist from the measurement device. In addition, the controller computer may be configured to determine at least one parameter of a process module in response to the measured property of the resist. For example, the controller computer may be configured to use an experimentally determined or a numerically simulated relationship between the property and the parameter to determine a parameter in response to the property. The controller computer may be further configured to control the process module such that the parameter may be altered in response to the determined parameter. Therefore, the altered parameter of the process step may be a function of at least one measured property of the resist. The controller computer may also be configured to control the measurement device to measure the physical property of the resist.

In an additional embodiment, the system may be configured to monitor variations in at least one property of the resist. For example, a measurement device may be configured to measure a property of the resist substantially continuously or at predetermined time intervals during a step of the lithography process. A controller computer coupled to the system may, therefore, receive the measured property from the measurement device and may monitor variations in the property over the duration of a process step of the lithography process. By analyzing the variations in at least one property of the resist during a step of the lithography process, the controller computer may also generate a signature representative of a process step such as a PEB process. The signature may include at least one singularity which may be characteristic of an endpoint of the PEB process. An appropriate endpoint for the process step may be a linewidth or a thickness of a latent image in the resist formed during the PEB process. The linewidth or the thickness of the latent image may be larger or smaller depending upon the semiconductor device feature being fabricated by the lithography process. After the controller computer may have detected the singularity of the signature, the controller computer may stop the PEB process by altering a level of a parameter of an instrument coupled to the PEB process module.

In an embodiment, a method for fabricating a semiconductor device may include a lithography process in which a pattern may be transferred from a reticle to a resist. For example, portions of the resist may be removed using a lithography process such that regions of the wafer or an underlying layer may be exposed to a subsequent process such as an ion implantation process. The predetermined regions may be regions of the wafer or the underlying layer in which features of a semiconductor device are to be formed such as, for example, source/drain junctions. Fabricating a semiconductor device may also include evaluating and controlling a lithography process by measuring at least one property of a resist disposed upon a wafer during the lithography process. In addition, measuring at least one property of the resist may include measuring within wafer variations in at least one property of the resist during the lithography process. The physical property of the resist may be altered by a process step of the lithography process.

The method for fabricating a semiconductor device may also include determining and/or altering at least one parameter of a process module which may be configured to perform a step of the lithography process. The altered parameter may be determined in response to at least one measured property of the resist to reduce within wafer variations of a critical metric of the lithography process. For example, the altered parameter may be determined using a function which describes a relationship between the physical property of the resist and a parameter of the process step of the lithography process. The altered parameter may also be determined independently at various positions within a field or within several fields of the wafer. In this manner, semiconductor devices fabricated by the method may have higher performance bin distributions thereby improving not only yield but also high margin product yield. In addition, the method for fabricating a semiconductor device may include processing a wafer to form at least a portion of at least one semiconductor device upon the wafer. For example, processing the wafer may include at least one semiconductor fabrication process such as etching, ion implantation, deposition, chemical mechanical polishing, plating, and/or any other semiconductor fabrication process known in the art.

A set of data may be collected and analyzed that may used to determine a parameter of a process module in response to a measured property of a resist formed upon a wafer. Process control methods as described herein may also be used to further optimize a lithography process by using optical measurements as described herein in conjunction with electrical measurements of a semiconductor device that may be formed with the lithography process. The combination of optical and electrical measurements may provide a larger amount of characterization data for a lithography process. In this manner, the characterization data may be used to understand the mechanisms of lithography, to pin-point the cause of defects, and to make accurate adjustments to parameters of various process modules, or the process conditions. In addition, such a process control strategy may be used to qualify, or characterize the performance of, a new lithography tool. The process control method may also be used to compare the performance of several similar lithography tools. Such a comparison may be used, for example, in a manufacturing environment in which several tools may be used in parallel to manufacture one device or product. Furthermore, this process control strategy may be used to determine an appropriate resist and thickness in the development stages of defining a lithography process.

In an embodiment, a quantitative relationship may be developed between a parameter of a process module that may be varied and a property of a resist. For example, a number of wafers may be processed using variations of a parameter of the process module. All other parameters of the process module and additional process modules may remain constant, and a correlation between the varied parameter and a property of the resist may be developed. In this manner, an algorithm that describes the quantitative relationship between each of the process parameters for a process module and the measured property of the resist may be determined. The developed algorithms may be used during processing of product wafers to determine if the process is operating within design tolerance for a process and a process module. Additionally, algorithms may be developed and used to further optimize a current process, to characterize a new process module, or to develop processes to fabricate next generation devices.

Furthermore, this algorithm may be integrated into a controller for a measurement device or a process module. The controller may by a computer system configured to operate software to control the operation of a measurement device such as a scatterometer, an interferometer, a reflectometer, a spectroscopic ellipsometer, or a spectroscopic reflectometer. The computer system may include a memory medium on which computer programs for operating the device and performing calculations related to the collected data. The term “memory medium” is intended to include an installation medium, e.g., a CD-ROM, or floppy disks, a computer system memory such as DRAM, SRAM, EDO RAM, Rambus RAM, etc., or a non-volatile memory such as a magnetic media, e.g., a hard drive, or optical storage. The memory medium may include other types of memory as well, or combinations thereof. In addition, the memory medium may be located in a first computer in which the programs are executed, or may be located in a second different computer that connects to the first computer over a network. In the latter instance, the second computer provides the program instructions to the first computer for execution. Also, the computer system may take various forms, including a personal computer system, mainframe computer system, workstation, network appliance, Internet appliance, personal digital assistant (PDA), television system or other device. In general, the term “computer system” may be broadly defined to encompass any device having a processor which executes instructions from a memory medium.

The memory medium preferably stores a software program for the operation of a measurement device and/or a process module. The software program may be implemented in any of various ways, including procedure-based techniques, component-based techniques, and/or object-oriented techniques, among others. For example, the software program may be implemented using ActiveX controls, C++ objects, JavaBeans, Microsoft Foundation Classes (MFC), or other technologies or methodologies, as desired. A CPU, such as the host CPU, executing code and data from the memory medium includes a means for creating and executing the software program according to the methods described above.

Various embodiments further include receiving or storing instructions and/or data implemented in accordance with the foregoing description upon a carrier medium. Suitable carrier media include memory media or storage media such as magnetic or optical media, e.g., disk or CD-ROM, as well as signals such as electrical, electromagnetic, or digital signals, conveyed via a communication medium such as networks and/or a wireless link.

The software for a measurement device may then be used to monitor and predict the processing conditions of subsequent lithography processes. Preferably, the predefined algorithm for a process step of the lithography process may be incorporated into the software package that interfaces with the measurement device. In this manner, the software may be configured to receive data that may be measured by the measurement device. The software may also be configured to perform appropriate calculations to convert the data into properties of the resist. Additionally, the software may also be configured to compare a property of a resist formed on a product wafer to a property of a resist formed on a reference wafer for a lithography process. In this manner, the software may be configured to convert variations in the properties to variations that may occur in the process conditions. Furthermore, by incorporation of the appropriate algorithm, the software may also be configured to convert the properties of a resist into meaningful data about the process conditions of the lithography process including a characteristic of an exposure step or a characteristic of a PEB step.

A method to evaluate and control a lithography process using field level analysis as described above may provide dramatic improvements over current process control methods. Measuring within wafer variability of critical metrics, or critical dimensions, may provide tighter control of the critical dimension distribution. In addition to improving the manufacturing yield, therefore, the method described above may also enable a manufacturing process to locate the distribution performance of manufactured devices closer to a higher performance level. As such, the high margin product yield may also be improved by using such a method to evaluate and control a lithography process. Furthermore, additional variations in the lithography process may also be minimized. For example, a process may use two different PEB units to process one lot of wafers. Two bake units may be used to perform the same process such that two wafers may be processed simultaneously in order to reduce the overall processing time. Therefore, the above method may be used to evaluate and control each bake unit separately. As such, the overall process spread may also be reduced.

The data gathered in accordance with the present invention may be analyzed, organized, and displayed in any suitable means. For example, the data could be grouped across the wafer as a continuous function of radius, binned by radial range, binned by stepper field, by x-y position (or range of x-y positions, such as on a grid), by nearest die, and/or other suitable methods. The variation in data may be reported by standard deviation from a mean value, the range of values, and/or any other suitable statistical method.

The extent of the within wafer variation (such as the range, standard deviation, and the like) may be analyzed as a function of wafer, lot, and/or process conditions. For example, the within wafer standard deviation of the measured CD may be analyzed for variation from lot to lot, wafer to wafer, and the like. It may also be grouped, reported, and/or analyzed as a function of variation in one or more process conditions, such as develop time, photolithographic exposure conditions, resist thickness, post-exposure bake time and/or temperature, pre-exposure bake time and/or temperature, and the like. It may also or instead be grouped, reported, and/or analyzed as a function of within wafer variation in one or more of such processing conditions.

The data gathered in accordance with the present invention may be used not just to better control process conditions, but also where desirable to better control in situ endpointing and/or process control techniques. For example, data gathered in accordance with the present invention may be used in conjunction with an apparatus such,as that set forth in U.S. Pat. No. 5,689,614 to Gronet et al. and/or Published European patent Application No. EP 1066925 to Zuniga et al., which are hereby incorporated by reference as if fully set forth herein, to improve the control over localized heating of the substrate or closed loop control algorithms. Within wafer variation data could be fed forward or back to such a tool to optimize the algorithms used in control of local wafer heating or polishing, or even to optimize the tool design. In another example of such localized process control, within wafer variation data could be used to control or optimize a process or tool such as that set forth in one or more of Published PCT Patent Application Nos. WO 99/41434 to Wang or WO 99/25004 to Sasson et al. and/or Published European Patent Application No. 1065567 to Su, which are hereby incorporated by reference as if fully set forth herein. Again, within wafer variation data taken, for example, from stand alone and/or integrated measurement tools, could be used to better control and/or optimize the algorithms, process parameters and integrated process control apparatuses and methods in such tools or processes. Data regarding metal thickness and its within wafer variation could be derived from an x-ray reflectance tool such as that disclosed in U.S. Pat. No. 5,619,548 to Koppel and/or Published PCT Application No. WO 01/09566 to Rosencwaig et al., which are hereby incorporated by reference as if fully set forth herein, by eddy current measurements, by e-beam induced x-ray analysis, or by any other suitable method.

In general, an embodiment of a system configured to control variation in dimensions (e.g., line width) of patterned features across a wafer includes a device and a control subsystem. The device is configured to measure a characteristic of a latent image formed in a resist at more than one location across a wafer during a lithography process. The control subsystem is configured to alter a parameter of the lithography process in response to the characteristic to reduce variation in dimensions of patterned features formed across the wafer by the lithography process. Altering the parameter compensates for non-time varying spatial variation in a temperature to which the wafer is exposed during a PEB step of the lithography process and an additional variation in the PEB step.

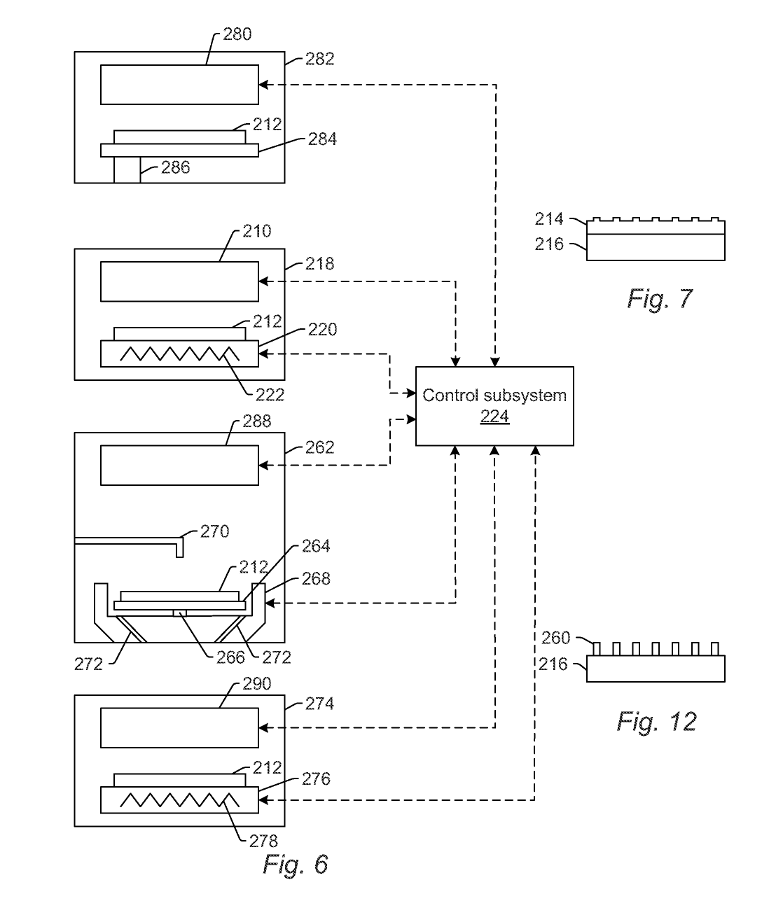

One embodiment of such a system is shown in FIG. 6. As shown in FIG. 6, the system includes device 210. Device 210 is configured to measure a characteristic of a latent image formed in a resist at more than one location across wafer 212 during a lithography process. A latent image or a “relief image” is generally defined by variations in the thickness of a resist across the resist after exposure of the resist and before development of the resist. For instance, after exposure, the exposed areas of the resist may have a thickness that is less than the thickness of non-exposed areas of the resist due to a reaction that takes place in the exposed areas during the exposure step. One example of a latent image formed in a resist is shown in FIG. 7. In particular, resist 214 formed on wafer 216 has varying thickness across the wafer. Areas of resist 214 that have a reduced thickness include areas of the resist that were exposed to an energy source by an exposure tool (e.g., a scanner or a stepper).

The characteristic(s) of the latent image may be relatively constant between exposure and initiation of the PEB step. During the PEB step, however, one or more characteristics of the latent image may change. For instance, the thickness of areas of resist 214 that have a reduced thickness subsequent to exposure may be further reduced by one or more reactions in the resist that are caused by the energy to which the wafer is exposed during the PEB step. One or more characteristics of the latent image formed in resist 214 may be measured by device 210. The characteristic(s) of the latent image that may be measured by device 210 may include any characteristic(s) of the latent image described herein. In addition, device 210 may be further configured as described herein.

As shown in FIG. 6, device 210 may be incorporated into (i.e., disposed within) PEB module 218. Therefore, in one embodiment, device 210 is configured to measure one or more characteristic(s) of the latent image during the PEB step performed on wafer 212. For instance, PEB module 218 includes PEB plate 220 on which wafer 212 is positioned during the PEB step. PEB plate 220 may be further configured as described herein. For instance, although PEB plate 220 is generally shown in FIG. 6 as including resistive heating element 222 that is configured to generate the heat to which wafer 212 is exposed during the PEB step, it is to be understood that PEB plate 220 may include multiple resistive or other heating elements (not shown in FIG. 6) that may be further configured as described herein.

While wafer 212 is positioned on PEB plate 220, device 210 can perform the measurements described herein. Device 210 is, therefore, configured to perform in situ measurements of the characteristic(s) of the latent image. In addition, device 210 may be configured to perform in situ measurements of the characteristic(s) of the latent image at various times during the PEB step. In this manner, the device may configured to generate measurements that are sensitive to the changes in the latent image during the PEB step. Therefore, the one or more characteristics of the latent image can be monitored continuously or intermittently during the PEB step. However, device 210 may be configured to perform measurements of the latent image before the PEB step (e.g., immediately after the wafer is moved into PEB module 218) or after the PEB step (e.g., before the wafer is removed from PEB module 218). As described further herein, device 210 can be used for monitoring of latent image x-wafer signatures using sensor types that have not been previously used for latent image measurements that are performed before, during, and/or after the PEB step.

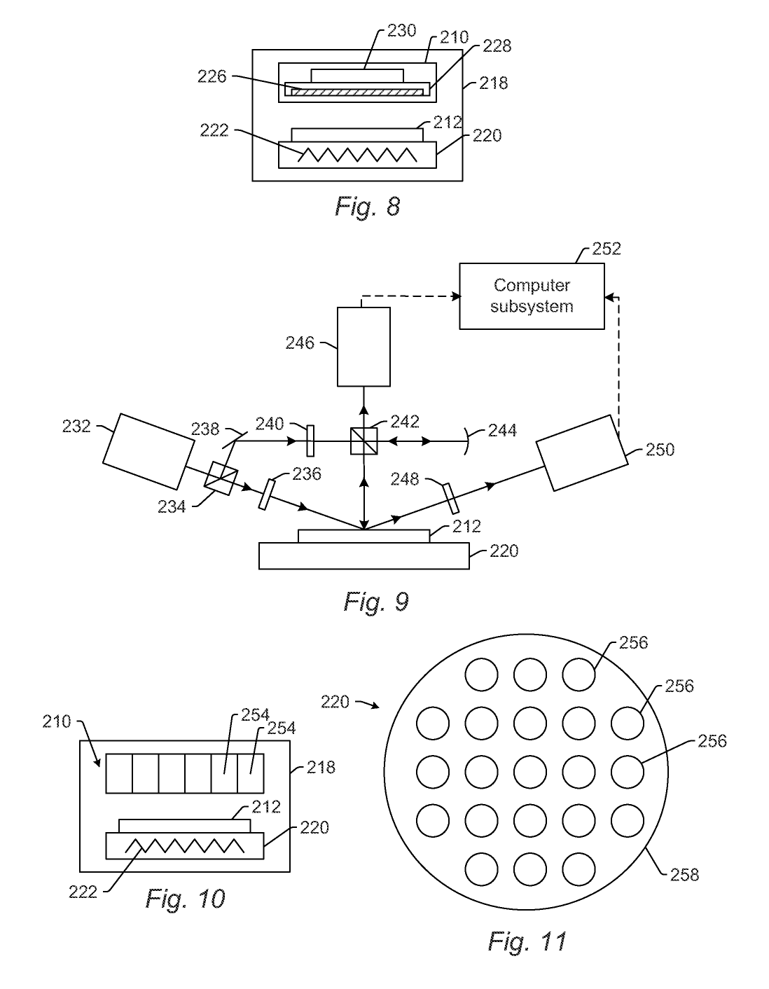

In one embodiment, device 210 is configured to measure byproducts of the PEB step and to determine the characteristic of the latent image from the byproducts. One such embodiment of device 210 is shown in FIG. 8. The device shown in FIG. 8 includes sensor 226 that is configured to detect and measure byproducts of the PEB step performed on wafer 212. For example, sensor 226 may be configured to detect byproducts (e.g., volatile organic materials) that are outgassed from the resist formed on wafer 212 during the PEB step. In this manner, outgassing above PEB plate 220 can be measured during and/or after the PEB step. Therefore, the measurements described herein can be performed by measuring byproducts produced during the PEB step. In another example, sensor 226 may be configured to detect materials deposited on the surface of the sensor during the PEB step. The deposited byproducts can be measured during and/or after the PEB step. In this manner, the device may be configured to perform the measurements using chemical composition monitoring of the wafer. Sensor 226 may include any sensor that can be used to detect a presence of materials, a quantity of materials, the composition of materials, etc. produced during the PEB step.

Although sensor 226 is shown to have a lateral dimension (e.g., a width or a length) that is about the same as the width of wafer 212, it is to be understood that sensor 226 may have any suitable dimensions known in the art. In addition, although sensor 226 is shown in FIG. 8 to be disposed above wafer 212, it is to be understood that sensor 226 may be positioned at any suitable location within PEB module 218. Alternatively, sensor 226 may not be disposed within PEB module 218. Instead, sensor 226 may be located in a conduit or other structure coupled to the PEB module through which byproducts of the PEB step are removed from the PEB module.

Sensor 226 may be disposed within housing 228. Housing 228 may be configured to maintain a position of sensor 226 within PEB module 218. Housing 228 may have any suitable configuration known in the art. One or more components (not shown) may also be disposed in housing 228 such as components that are configured to couple sensor 226 to one or more electronic components 230 such as a computer subsystem. The one or more electronic components 230 may be configured to provide an interface between sensor 226 and the control subsystem (not shown in FIG. 8).

In another embodiment, device 210 shown in FIG. 6 also or alternatively includes an optical device. In some embodiments, the device is configured to measure the characteristic of the latent image at more than one wavelength. In another embodiment, the device is configured to measure the characteristic of the latent image across a spectrum of wavelengths. In an additional embodiment, the device is configured to optically form an image of the latent image and to determine the characteristic from the image. The device may be configured to perform the measurements using scatterometry, ellipsometry, reflectometry, polarized reflectometry, interferometry, or some combination thereof.

One embodiment of a device that can be used to perform the measurements described herein is shown in FIG. 9. The device shown in FIG. 9 includes light source 232. Light source 232 may include a single wavelength light source such as a laser. However, in many instances, it may be advantageous for the device to be configured to perform measurements at more than one wavelength. In one such instance, light source 232 may include a polychromatic light source such as a multi-wavelength laser if the device is configured to measure the characteristic of the latent image at more than one wavelength. In another alternative, light source 232 may include a broadband light source such as an arc lamp if the device is configured to measure the characteristic of the latent image across a spectrum of wavelengths. Light source 232 may include any other suitable light source known in the art.

Light from light source 232 may be directed to wafer 212 at an oblique angle of incidence. In some embodiments, light from light source 232 may also or alternatively be directed to wafer 212 at a normal angle of incidence. For instance, the device may include beam splitter 234. Beam splitter 234 may include any suitable beam splitter known in the art. Beam splitter 234 may transmit a portion of the light from light source 232 to polarizing component 236. Polarizing component 236 may include any suitable polarizing component known in the art. Light transmitted by polarizing component 236 is directed to wafer 212 at an oblique angle of incidence. The oblique angle of incidence may be any suitable oblique angle of incidence known in the art.

Beam splitter 234 may reflect the other portion of the light from light source 232 to reflective optical component 238. Reflective optical component 238 may include any suitable reflective optical component known in the art such as a flat mirror. Reflective optical component 238 is configured to direct the light through polarizing component 240 to beam splitter 242. Polarizing component 240 may include any suitable polarizing component known in the art. Beam splitter 242 may include any suitable beam splitter known in the art. Beam splitter 242 may reflect a portion of the light to wafer 212 at a substantially normal angle of incidence. Beam splitter 242 may also transmit a portion of the light to reflective optical component 244. Reflective optical component 244 may include any suitable reflective optical component known in the art such as a curved mirror.

Normal incidence illumination reflected from wafer 212 may be transmitted by beam splitter 242 to detector 246. Light reflected from reflective optical component 244 may be reflected by beam splitter 242 to detector 246. The device may also include polarizing component 248 through which oblique incidence illumination reflected or scattered from wafer 212 may pass. Polarizing component 248 may include any suitable polarizing component known in the art. Light that passes through polarizing component 248 is detected by detector 250.

Detectors 246 and 250 may be selected based on the wavelength(s) used for the measurements. In addition, the detectors may be selected based on the type of measurements to be performed by the device. For instance, the detectors may include imaging detectors if the device is configured to optically form an image of the latent image.

Detectors 246 and 250 are coupled to computer subsystem 252 via transmission media shown by the dashed lines in FIG. 9. The transmission media may include any suitable transmission media known in the art. In this manner, the computer subsystem may receive output signals generated by detectors 246 and 250. Computer subsystem 252 may also be configured to use the output signals to determine one or more characteristics of the latent image.

Computer subsystem 252 may take various forms, including a personal computer system, mainframe computer system, workstation, image computer, parallel processor, or any other device known in the art. In general, the term “computer system” may be broadly defined to encompass any device having one or more processors, which executes instructions from a memory medium. Computer subsystem 252 may be further configured as described herein.

The components of the device shown in FIG. 9 that are included in a particular embodiment of the device or are used for a particular measurement can vary depending on the measurement technique or techniques that are selected. For instance, as described above, the device may be configured to perform measurements of a latent image formed on wafer 212 using scatterometry, ellipsometry, reflectometry, polarized reflectometry, interferometry, or some combination thereof.

In one such embodiment, if the device is configured to perform scatterometry measurements, the device may be configured to direct light from light source 232 to wafer 212 at an oblique angle of incidence. In this embodiment, beam splitter 234 and polarizing component 236 may not be included in the device or may be moved out of the illumination path of the device during these measurements. In addition, in this embodiment, polarizing component 248 may not be included in the device or may be moved out of the collection path of the device during these measurements. Light-scattered from the wafer is detected by detector 250. In particular, light scattered by the features of the latent image into one or more diffraction orders may be detected by detector 250. In this manner, output signals generated by detector 250 are scatterometry measurements of the latent image. The device may be configured to perform the scatterometry measurements at a single wavelength, at more than one wavelength, or across a spectrum of wavelengths (i.e., spectroscopic scatterometry).

In another such embodiment, if the device is configured to perform ellipsometry measurements, the device may be configured to direct light from light source 232 through polarizing component 236 to wafer 212 at an oblique angle of incidence. Therefore, polarizing component 236 may be configured to function as a polarizer in this embodiment. In this embodiment, beam splitter 234 may not be included in the device or may be moved out of the illumination path during these measurements. Light reflected from the wafer passes through polarizing component 248 and is detected by detector 250. Therefore, polarizing component 248 may be configured to function as an analyzer in this embodiment, and output signals generated by detector 250 include ellipsometry measurements. The device may be configured such that polarizing component 236 or polarizing component 248 rotates during these measurements. Therefore, the device may be configured as a rotating polarizer ellipsometer or a rotating analyzer ellipsometer. In addition, the device may be configured to perform the ellipsometry measurements at a single wavelength, at more than one wavelength, or across a spectrum of wavelengths (i.e., spectroscopic ellipsometry).

In a further embodiment, if the device is configured to perform reflectometry measurements, the device may be configured to direct light from light source 232 to beam splitter 234. Light that is reflected by beam splitter 234 is directed to reflective optical component 238. Reflective optical component 238 directs the light to beam splitter 242. In this embodiment, polarizing component 240 may not be included in the device or may be moved out of the illumination path during the reflectometry measurements. Light reflected by beam splitter 242 is directed to wafer 212 at a substantially normal angle of incidence. In this embodiment, beam splitter 242 may not be configured to transmit a portion of the illumination to reflective optical component 244, or reflective optical component 244 may not be included in the device. Normal incidence illumination that is specularly reflected by wafer 212 passes through beam splitter 242 and is detected by detector 246. In this manner, output signals generated by detector 246 include reflectometry measurements of the latent image. The device may be configured to perform the reflectometry measurements at a single wavelength, at more than one wavelength, or across a spectrum of wavelengths (i.e., spectroscopic reflectometry).

In another embodiment, if the device is configured to perform polarized reflectometry, the device may be configured as described for reflectometry measurements. However, for polarized reflectometry measurements, polarizing component 240 may be disposed in the illumination path as shown in FIG. 9. In this embodiment, polarizing component 240 may be configured such that light can be directed to wafer 212 at a selected polarization or at a variety of polarizations. In this manner, output signals generated by detector 246 include polarized reflectometry measurements of the latent image. The device may be configured to perform the polarized reflectometry measurements at a single wavelength, at more than one wavelength, or across a spectrum of wavelengths (i.e., spectroscopic polarized reflectometry).

In some embodiments, if the device is configured to perform interferometry measurements of the wafer, the device may be configured to direct light from light source 232 to beam splitter 234. Light that is reflected by beam splitter 234 is directed to reflective optical component 238. Reflective optical component 238 directs the light to beam splitter 242. In this embodiment, polarizing component 240 may not be included in the device or may be moved out of the illumination path during the interferometry measurements. Light reflected by beam splitter 242 is directed to wafer 212 at a substantially normal angle of incidence. Light transmitted by beam splitter 242 is directed to reflective optical component 244. Light reflected by the wafer is transmitted through beam splitter 242. In addition, light reflected from reflective optical component 244 is reflected by beam splitter 242. Therefore, the light reflected by the wafer and the light reflected by optical component 244 may interfere, and the interference between the two beams of light can be detected by detector 246. In this manner, output signals generated by detector 246 can include interferometry measurements of the latent image. The device may be configured to perform the interferometry measurements at a single wavelength, at more than one wavelength, or across a spectrum of wavelengths.

The device shown in FIG. 9 may also or alternatively be configured as a “correlation spectrometer.” In this manner, a correlation spectrometer may also or alternatively be used for the measurements described herein. Examples of a correlation spectrometer are described in U.S. Pat. No. 4,355,903 to Sandercock and U.S. Pat. No. 5,241,366 to Bevis et al., which are incorporated by reference as if fully set forth herein. The rotating disk of the spectrometers described in these patents can also be replaced by a simpler apparatus which uses a translator (such as a piezoelectric translator) to change the distance between a mirror and a beam splitter in the optical path. The embodiments of the device described herein may be further configured as described in these patents.

The device shown in FIG. 9 is, therefore, advantageously configured to perform different types of measurements of wafer 212 including scatterometry, ellipsometry, reflectometry, polarized reflectometry, and interferometry measurements by altering the position of one or more of the components of the device shown in FIG. 9. Such a configuration is advantageous since multiple types of measurements may be used in combination to determine more characteristics or more accurate characteristics of the latent image. Of course, device 210 may be configured to perform only a subset of these measurement techniques. For example, device 210 may be configured for scatterometry and ellipsometry measurements of the latent image. In another example, device 210 may be configured for reflectometry and interferometry measurements of the latent image. In addition, device 210 may be configured to perform two or more of any of the measurement techniques described herein on the latent image formed on wafer 212.

Furthermore, although one configuration of the device is shown in FIG. 9, it is to be understood that various changes can be made to the device, and the device will still be configured within the scope of the embodiments described herein. For instance, one or more lenses (not shown) may be positioned in the illumination paths and the collection paths of the device. In addition, the angles and the spacings between the optical components may be varied from that shown in FIG. 9, for example, to optimize performance of the device. The single light source shown in FIG. 9 may also be replaced by multiple light sources (not shown) (e.g., one for normal incidence illumination and one for oblique incidence illumination). The multiple light sources may be light sources of the same or different types.

As described above, the device may be configured to perform measurements of a latent image formed on a wafer using spectral methods. Data from spectral methods can be analyzed by computer subsystem 252 in several ways. For example, full data analysis can be performed in the same manner in which scatterometry critical dimension (CD) measurements are performed. Alternatively, relative methods can be used to track changes in the acquired spectra over time. One such relative method includes comparing peak shifts measured at one or more different locations on the wafer to predetermined spectra such as previously acquired spectra or calculated spectra. The spectra measured at different sites may optionally be used in such measurements to make the measurements more robust.

In one such example, at each measurement site, the reflectivity may be measured as function of wavelength (λ). In this example, Fourier transforming may be used to identify the peak(s) that relate(s) to film thickness(es) (resist and any underlying films). In addition, the shift and/or widening of the peak(s) may be monitored as the PEB step progresses and causes a latent image to be created on the wafer. In other words, the shift and/or widening of the peak(s) can be used to determine the progress of the PEB step since the changes in the peak(s) are indicative of chemical and/or physical changes in the resist. The method may also include correcting for dispersion (e.g., changes in index of refraction as function of wavelength) to obtain sharper peaks thereby allowing more sensitive detection of broadening and shift.

The device may also be configured to perform the above described measurements at selected, specific wavelengths at which constituents of the resist (such as solvent, photo-active generating (PAG) compound, etc.) exhibit particularly pronounced absorption or refraction. The device embodiments described herein may also be configured to perform the measurements by directly monitoring the chemical composition of the resist or byproducts of PEB step using laser diodes (not shown).

As described above, the device may be configured to optically form an image of the latent image. In particular, measurement data can be collected as one or more one-dimensional or two-dimensional images. In such embodiments, the characteristic(s) of the latent image can be determined from the image. For example, by analyzing the intensity/pixel number as a function of path difference, the peak change and/or broadening can be monitored (like the reflectometry embodiment described above) as the relief or latent image is created in the resist during the PEB step. In addition, individual pixels or groups of pixels can be analyzed to characterize cross wafer uniformity.

The device may be configured to perform measurements on a test structure in the latent image, a die in the latent image, or the latent image formed across the whole wafer. In addition, the systems described herein may be configured to select an area to analyze from the whole field of view (FOV) of the measurement device.

Device 210 may be configured to measure the characteristic(s) of the latent image formed in the resist at more than one location across wafer 212 during the PEB step of a lithography process performed on wafer 212. Device 210 may be configured to measure the characteristic(s) at more than one location across wafer 212 in any suitable manner known in the art. For example, as described further herein, the measurements can be made at more than one discrete location across the wafer either sequentially (e.g., by moving the wafer (via movement of the PEB plate) and/or the measurement head) or in parallel (e.g., using multiple measurement heads).

Measuring the characteristic(s) of the latent image at more than one location across the wafer is advantageous for a number of reasons. For example, for measurements performed using scatterometry, the device can measure test sites across the wafer such that the measurements are responsive to the changes in surface topography of the resist and modulation of optical properties of the resist as the latent image develops on the wafer during the PEB step. The parameter of interest is mostly the depth (or height) of features in the latent image in the resist; and therefore, the scatterometry measurements can be relatively simple and similar to the spectral methods above. In another example, for measurements performed using common path interferometry, similar to above, the device can be configured to measure either a whole die or test structures that can be identified from the entire FOV of the measurement device.

In some embodiments, device 210 is configured to measure the characteristic(s) of the latent image at the more than one location sequentially. Sequential measurements at multiple locations across a wafer may be achieved in a number of ways. For instance, the device may be configured to alter the location at which the FOV of the device is positioned on wafer 212. Altering the location of the FOV of the device on the wafer may be performed by physically altering the position of device 210 above wafer 212. Physically altering the position of device 210 may be performed in any suitable manner known in the art. Alternatively, altering the location of the FOV of the device on the wafer may be performed by optical components (not shown in FIG. 6) included in the device such as a acousto-optic deflector (AOD) or any other suitable mechanical or optical scanning component known in the art.

Altering the location of the FOV of the device on wafer 212 may also or alternatively be performed by altering a position of the wafer within PEB module 218. For example, PEB plate 220 may be coupled to an assembly (not shown) that may be configured to mechanically or robotically alter the position of PEB plate 220 within PEB module 218 and therefore the position of wafer 212 within PEB module 218. The assembly may include any suitable mechanical or robotic assembly known in the art. The assembly may be controlled by device 210 (e.g., by a computer subsystem (not shown in FIG. 6) of the device, which may be configured as described herein) or another control subsystem of the system (e.g., control subsystem 224).

In a different embodiment, device 210 is configured to measure the characteristic(s) of the latent image at more than one location across wafer 212 simultaneously. For instance, device 210 may be configured as a multi-spot device. In other words, device 210 may be configured to direct light to and collect light from multiple locations on the wafer simultaneously such that measurements can be performed at the multiple locations simultaneously. In one such example, multiple spots on the wafer may be illuminated using a diffractive optical element (not shown) positioned in the illumination path of the device, and light collected from the illuminated spots may be detected by an array of detectors (not shown) or a detector such as detector 246 or 250 having an array of photosensitive elements.

In a different embodiment, device 210 may include multiple measurement subsystems (not shown in FIG. 6), each of which may be used to measure the characteristic(s) of the latent image at multiple locations on wafer 212 in parallel. One such embodiment of device 210 is illustrated in FIG. 10. In particular, as shown in FIG. 10, one embodiment of device 210 includes multiple measurement subsystems 254. Each of the measurement subsystems (or “measurement heads”) may be configured to measure the characteristic(s) of the latent image at a different location on the wafer. In this manner, some or all of the measurement subsystems may perform measurements on the wafer simultaneously. Each of the measurements subsystems may be configured similarly. In addition, each of the measurement subsystems may be configured to perform one or more of the measurement techniques described herein. Furthermore, each of the measurement subsystems may be coupled to a computer subsystem (not shown in FIG. 10) such as computer subsystem 252 described further above. In this manner, the computer subsystem may be configured to use measurements performed by each of the measurement subsystems to alter the parameter of the lithography process as described further herein.

As shown in FIG. 10, the measurement subsystems may be arranged in a one-dimensional array. In one such embodiment, the one-dimensional array of measurement subsystems may be configured such that the position of the one-dimensional array of measurement subsystems can be altered with respect to wafer 212. In this manner, each of the measurement subsystems in the array can measure the characteristic(s) of the latent image at more than one location on the wafer sequentially. In other words, the position of the one-dimensional array may be altered with respect to wafer 212 such that the one-dimensional array of measurement subsystems scans across the wafer (e.g., in a stepwise manner). In a different embodiment, the device may include a two-dimensional array (not shown) of measurement subsystems. The two-dimensional array of measurement subsystems may or may not span an entire area of the wafer. In addition, the position of the two-dimensional array of measurement subsystems may or may not be altered as described above.

Furthermore, although the device is shown in FIG. 10 as including a particular number of measurement subsystems, it is to be understood that the device may include any suitable number of measurement subsystems configured in any suitable arrangement. Although the embodiment of the device shown in FIG. 10 is incorporated into PEB module 218, it is to be understood that such a device may be coupled to a lithography tool in any other manner described herein such that the device can perform measurements of the latent image at other points during the lithography process.

Incorporating device 210 into PEB module 218 may be advantageous for a number of reasons. For instance, since device 210 is configured to measure characteristic(s) of the latent image formed on wafer 212 during the PEB step at more than one location across wafer 212, the measurements are sensitive to all variations in the parameters of the PEB step. In particular, the measurements are sensitive to non-time varying spatial variation in a temperature to which wafer 212 is exposed during the PEB step of the lithography process. The measurements are also sensitive to additional variations in the PEB step including time varying spatial variation in the temperature, variation in energy transfer to the wafer, and variation in time between an exposure step of the lithography process and initiation of the PEB step. As such, the measurements can be used to control the parameters of the PEB step (and/or possibly other step(s) of the lithography process as described further herein) to compensate for these variations.

In particular, control subsystem 224 is configured to alter a parameter of the lithography process in response to the characteristic of the latent image to reduce variation in dimensions of patterned features formed across the wafer by the lithography process. As shown in FIG. 6, control subsystem 224 may not be included in device 210. In other words, control subsystem may be external to device 210. Such an embodiment of the control subsystem may be advantageous in instances such as when device 210 is incorporated into PEB module 218 or another process module of a lithography tool. In this manner, space within the module or modules is not occupied by control subsystem 224. Instead, control subsystem 224 may be coupled to device 210 by a transmission medium (shown in FIG. 6 by the dashed line). The transmission medium may include any suitable transmission medium known in the art. The device may send measurement results to the control subsystem via the transmission medium. In addition, the control subsystem may send one or more instructions to the device via the transmission medium. In this manner, the control subsystem may be configured to alter and control one or more parameters of the device.

As described above, therefore, control subsystem 224 may be configured to receive measurements of the latent image from device 210. Control subsystem 224 may use the measurements to determine if and how one or more parameters of the lithography process can or should be altered to reduce and control variation in dimensions of patterned features formed across wafer 212. For instance, control subsystem 224 may be configured to alter one or more parameters of PEB plate 220. Control subsystem 224 may be coupled to PEB plate 220 by a transmission medium (as shown in FIG. 6 by the dashed line). Control subsystem 224 may be configured to alter the one or more parameters of PEB plate 220 directly (by directly controlling a component of the PEB plate) or indirectly (by sending the one or more parameter alterations to a local control subsystem of the PEB plate).

As described above, therefore, control subsystem 224 receives measurements from device 210 that are sensitive to non-time varying spatial variation in a temperature to which the wafer is exposed during a PEB step of the lithography process, time varying spatial variation in the temperature, variation in energy transfer to the wafer, and variation in time between an exposure step of the lithography process and initiation of the PEB step. Since control subsystem 224 determines which parameter(s) and how the parameter(s) of the lithography process are to be altered in response to the characteristic, altering parameter(s) as described above compensates for the variations to which the measurements are sensitive. In particular, altering the parameter(s) compensates for non-time varying spatial variation in a temperature to which the wafer is exposed during a PEB step of the lithography process and an additional variation in the PEB step. The additional variation includes time varying spatial variation in the temperature, variation in energy transfer to the wafer, and variation in time between an exposure step of the lithography process and initiation of the PEB step.

The control subsystem may be configured to determine the parameter(s) of the lithography process that are to be altered in any manner (e.g., using any suitable method, algorithm, data structure, etc.). For instance, the control subsystem may receive latent image thickness (e.g., average thickness) measured at multiple locations on the wafer. Based on the latent image thickness measured at one location on the wafer and a predetermined relationship between total energy transferred to the wafer during the PEB step (which may be correlated to the temperature to which that location of the wafer is exposed during the PEB step) and the final latent image thickness (which may be correlated to the dimensions of patterned features formed across the wafer), the control subsystem may be configured to determine the temperature to which that location on the wafer should be exposed during the PEB step. In addition, the control subsystem may be configured to determine the temperature to which that location on the wafer should be exposed throughout the PEB step (i.e., temperature as a function of time).

The predetermined relationship may be determined experimentally or empirically. The predetermined relationship may also be defined, stored, and used in any suitable format known in the art. Obviously, the example of how the control subsystem can determine a parameter of the PEB step from the characteristic described above is only one example of the how one measured latent image characteristic can be used to determine a parameter of the lithography process to be altered. The embodiments described herein can be used to alter any parameter of the lithography process that has some effect on the dimensions of patterned features formed across the wafer by the lithography process and that can be correlated to a characteristic of the latent image that can be measured by the device.

In some embodiments, therefore, the parameter that is altered by the control subsystem includes the temperature to which different portions of the wafer are exposed during the PEB step. For example, the measurement data collected by the device can be used to change the x-wafer bake process (e.g., using a dynamic plate design) while baking using an in situ control technique. In addition, or alternatively, as described further herein, the measurement data collected by the device can be used to alter one or more parameters of either an additional bake step (preferably, but optionally, with the ability to locally modify the heating of the wafer during the additional bake step) or a develop step using a feedforward (FF) control technique.

One embodiment of a PEB plate that can be used to alter the temperature to which different portions of the wafer are exposed during the PEB step is shown in FIG. 11. As shown in FIG. 11, PEB plate 220 includes multiple heating elements 256 disposed within plate substrate 258. Heating elements 256 may be resistive heating elements or any other suitable heating elements known in the art. Although a certain number and arrangement of heating elements 256 are shown in FIG. 11, it is to be understood that any suitable number of heating elements configured in any suitable arrangement may be included in PEB plate 220. Plate substrate 258 may be formed of any suitable material known in the art. The temperature of each of the multiple heating elements may be independently controlled by control subsystem 224 shown in FIG. 6. In this manner, the temperature to which different portions of the wafer are exposed may be independently controlled by the control subsystem.

In general, therefore, the systems described herein can be used to control the repeatability and uniformity of pattern profiles formed by a lithography process. In particular, the systems described herein can be used to reduce variation in the dimensions of patterned features formed by a lithography process by monitoring the progress of the reaction that takes place during the PEB step (e.g., by monitoring one or more parameters of the latent image during the PEB step) using one or more in situ sensors (or one or more in situ measurement devices) and optionally actively controlling the energy delivered to the wafer during the PEB step. The measurement device(s) may be further configured as described herein.

The primary sources of CD variations for 248 nm and 193 nm lithography are variations in one or more parameters of the exposure tool (e.g., a scanner) such as exposure dose, lens aberrations, and focal plane and one or more parameters of the lithography track such as variations in PEB time and temperature and photoresist development rate. PEB variation can be further partitioned into temporal and spatial variation of the PEB plate temperature and variation in the time between exposure and initiation of PEB. Reducing PEB variation is critical to lithographic CD control because of the high sensitivity of photoresist feature dimensions to PEB temperature (up to about 7 nm/C to about 8 nm/C).

The systems described herein can be used to correct for non-time varying spatial variation in the plate temperature similar to current methods. In addition, unlike currently used systems, the systems described herein can be used to correct for time varying spatial variation in plate temperature, variation in energy transfer from plate to wafer, and variation in photoresist reaction rate due to variation in the delay between exposure and initiation of PEB. Therefore, the systems described herein can be used to compensate for all factors that contribute to variation in reaction progress of a photoresist during the PEB step, including those which change with time or are driven by interaction of individual wafers with the PEB plate. These phenomena cannot be corrected using current technologies. In particular, current methods can only compensate for steady-state spatial variation in the PEB temperature. Furthermore, the systems described herein can be used to perform measurements at more than one measurement location across the wafer, not just at one location. In addition, the systems described herein can use more accurate methods to measure the latent image relief signature.

Therefore, the systems described herein have several advantages over currently used systems. For example, the systems described herein provide improved uniformity of dimensions of patterned features formed across a wafer and improved repeatability of dimensions of patterned features formed on more than one wafer. As such, the systems described herein can be used to reduce variation in the dimensions of circuit features defined by photolithography. In general, this enables improvements in both integrated circuit (IC) product performance and yield. In addition, by implementing the systems described herein, an equipment manufacturer can secure a substantial competitive advantage for a photoresist coat/develop track.

The systems described herein also enable new use cases for the collected data (modify one or more parameters of the PEB step, an additional bake step, or a develop step). For example, one or more parameters of a develop step and/or an additional bake step of the lithography process may be altered in response to the one or more characteristics of the latent image that are measured before, during, and/or after the PEB step. For example, control subsystem 224 shown in FIG. 6 may be configured to alter a parameter of a develop step performed during the lithography process after the PEB step. In this manner, the control subsystem may be configured to alter one or more parameters of the develop step using a feedforward control technique.

During the develop step, the portions of the resist that were or were not exposed (depending on whether the resist is a “positive” resist or a “negative” resist) during the exposure step may be removed by exposure to one or more chemicals (e.g., a developer). In this manner, subsequent to the develop step, patterned features 260 are formed on wafer 216 as shown in FIG. 12 from latent image 214 shown in FIG. 7. Preferably, the parameters of the develop step are altered to reduce variation in the characteristic of patterned features 260 formed across the wafer.

In one such embodiment, control subsystem 224 is coupled to develop module 262. Wafer 212 is positioned on stage 264 that is configured to support wafer 212 during the develop step. Stage 264 is coupled to shaft 266. Shaft 266 is coupled to a motor or another device (not shown) that is configured to rotate the stage. Develop module 262 also includes develop bowl 268 in which stage 264 and wafer 212 are disposed during the develop step. Once the wafer is positioned in the develop module, developer (not shown) is dispensed onto wafer 212 through conduit 270. For a period of time after the developer is dispensed onto the wafer, the position of the wafer may be stationary. After the period of time has elapsed, the motor or other device coupled to shaft 266 rotates stage 264 and thereby wafer 212 such that the developer is spun off of the wafer. Water (not shown) may then be dispensed on the wafer (e.g., through conduit 270 or another conduit (not shown)) during rotation of the wafer. Developer and water spun off of the wafer may be collected in develop bowl 268 and removed from the bowl through drains 272 formed in the bowl.

The one or more parameters of the develop step that may be altered by the control subsystem include, for example, the amount of developer dispensed on the wafer, the positions on the wafer on which the developer is dispensed, the amount of time that the developer is in contact with the wafer, the spin rate at which the developer is spun off of the wafer, the amount of water that is dispensed on the wafer, the locations on the wafer on which the water is dispensed, the spin rate at which the water is spun off of the wafer, or some combination thereof. The one or more parameters of the develop step may be determined by the control subsystem based on the characteristic of the latent image as described further above. Preferably, the parameter(s) of the develop step are altered by the control subsystem to reduce variation in dimensions of the patterned features across the wafer.

In another embodiment, control subsystem 224 is configured to alter a parameter such as a temperature to which different portions of the wafer are exposed during a bake step performed during the lithography process after the PEB step. For example, control subsystem 224 shown in FIG. 6 may be configured to alter a parameter of a bake step performed during the lithography process after the PEB step. In this manner, the control subsystem may be configured to alter one or more parameters of the additional bake step using a feedforward control technique.

A bake step that is performed after a develop step is commonly referred to as a “hard” bake step. Such an additional bake step may be performed to remove any water remaining on the wafer after the develop step, to remove any remaining solvent from the resist patterned features, or to “harden” the patterned features in preparation for additional processes performed on the wafer such as etch and scanning electron microscopy (SEM).

In one such embodiment, control subsystem 224 is coupled to bake module 274. Bake module 274 includes bake plate 276 on which wafer 212 is disposed during the bake step performed by bake module 274. As shown in FIG. 6, the bake plate may include resistive heating element 278. Although the heating element of bake plate 276 is shown in FIG. 6 as a resistive heating element, the bake plate may include any suitable heating element known in the art. In addition, bake plate 276 may be further configured as described herein. For example, bake plate 276 may be configured as shown in FIG. 11. As described above, the parameters of the bake step performed by bake module 274 that may be altered by the control subsystem include the temperature to which different portions of the wafer are exposed during the bake step. In this manner, the temperature to which different portions of the wafer are exposed during the additional bake step may be altered and controlled independently. The temperature of the different portions may be altered as described further above. The one or more parameters of the bake step may be determined by the control subsystem based on the characteristic of the latent image as described further above. Preferably, the parameter(s) of the additional bake step are altered by the control subsystem to reduce variation in dimensions of the patterned features across the wafer.

In another embodiment, bake module 274 may also or alternatively include one or more light sources (not shown) that are configured to illuminate the wafer and thereby heat the patterned features formed on the wafer. More than one light source may be used to heat the patterned features such that individual light sources can illuminate different portions of the wafer and can be independently controlled to heat the different portions of the wafer to different temperatures. The light source(s) may include any appropriate light sources known in the art that can be used to illuminate the wafer with any suitable wavelength or wavelengths of light. In this manner, the control subsystem may be coupled to the bake module such that the control subsystem can alter one or more parameters of the individual light sources to thereby alter a temperature to which different portions of the wafer are exposed during the additional bake step. The one or more parameters of the bake step may be determined by the control subsystem based on the characteristic of the latent image as described further above. Preferably, the parameter(s) of the additional bake step are altered by the control subsystem to reduce variation in dimensions of the patterned features across the wafer.

The information collected about the latent image formed in a resist at more than one location across a wafer can, therefore, be used to modify the PEB step x-wafer using dynamic fast responding elements that are able to change temperature locally and quickly (old methods only allowed modification of bake time that affects the whole wafer), feedforward to an additional bake process that uses heating elements and/or optically based heating to allow for x-wafer latent image modification, feedforward to a develop module to modify the x-wafer signature or lithographic pattern dimensions, or some combination thereof.

Although incorporating device 210 into PEB module 218 is advantageous for reasons described above, it is to be understood that device 210 may be arranged in other positions within the lithography tool and/or additional devices may be arranged in other positions within the lithography tool. For instance, in one embodiment (not shown), the device may be arranged external to the PEB module such that the characteristic of the latent image can be measured by the device before the wafer is moved into the PEB module, as the wafer is being moved into the PEB module, as the wafer is removed from the PEB module, or after the wafer is removed from the PEB module. In one such embodiment, the device may be coupled to a wafer handler (not shown) of the lithography tool. In another such embodiment, the device may be incorporated into a cooling module (not shown) configured to reduce the temperature of the wafer subsequent to the PEB step. In this manner, the device may be configured to measure characteristic(s) of the latent image subsequent to the PEB step and during the cooling step.

In another embodiment, as shown in FIG. 6, additional device 280 may be arranged in interface 282 of the lithography tool. Interface 282 may be configured to couple the lithography track (not shown) to the exposure tool (not shown). Therefore, wafers may be moved through interface 282 from the lithography track to the exposure tool and vice versa. In addition, wafers may be positioned in the interface for a period of time (e.g., before exposure and/or after exposure). In this manner, the period of time during which the wafers are “waiting” in the interface may be advantageously used to perform the measurements described herein.

In one such embodiment, interface 282 includes wafer handler 284 on which wafer 212 and other wafers may be moved from the lithography track to the exposure tool and vice verse. Wafer handler 284 may be attached to shaft 286. Shaft 286 may be coupled to a mechanical or robotic assembly (not shown) that is configured to translate and rotate wafer handler 284. Wafer handler 284 may include any suitable wafer handler known in the art. Wafer handler 284 may also be configured to hold wafers while they are waiting to be transferred to the lithography track or the exposure tool. In one such embodiment, additional device 280 may be configured to measure a characteristic of a latent image formed in a resist at more than one location across a wafer after the exposure step and while wafer 212 is disposed on wafer handler 284. Additional device 280 may be configured as described herein. In addition, device 210 and additional device 280 may be configured similarly or differently.

Control subsystem 224 may be coupled to additional device 280 as shown by the dashed line in FIG. 6. Control subsystem 224 may be further coupled to additional device 280 as described herein. Control subsystem 224 may be configured to alter one or more parameters of the lithography process based on the characteristic of the latent image measured by additional device 280. For example, control subsystem 224 may be configured to alter one or more parameters of PEB module 218 based on the characteristic of the latent image measured by the additional device. In this manner, the control subsystem may be configured to control the PEB step by feedforward control. Preferably, one or more parameters of the PEB step are altered by the control subsystem to reduce variation in the dimensions of patterned features formed on the wafer. The parameters fed forward to the PEB module may be determined and altered by the control subsystem as described further herein.

In an additional embodiment, as shown in FIG. 6, additional device 288 may be disposed within develop module 262. In this manner, additional device 288 may be configured to measure a characteristic of a latent image formed in a resist before the develop step while wafer 212 is disposed within develop module 262. In another embodiment, additional device 288 may be configured to measure a characteristic of patterned features formed on the wafer after the develop step while the wafer is disposed within develop module 262. Additional device 288 may be configured according to any of the embodiments described herein. In addition, device 210 and additional device 288 may be configured similarly or differently. Furthermore, if additional devices 280 and 288 are coupled to the lithography tool, additional devices 280 and 288 may be configured similarly or differently.

Control subsystem 224 may be coupled to additional device 288 as shown by the dashed line in FIG. 6. Control subsystem 224 may be further coupled to additional device 288 as described herein. Control subsystem 224 may be configured to alter one or more parameters of the lithography process based on the characteristic of the latent image or patterned features measured by additional device 288. For example, control subsystem 224 may be configured to alter one or more parameters of bake module 274 based on a characteristic of the latent image or the patterned features measured by the additional device. In this manner, the control subsystem may be configured to control the bake step by feedforward control. Preferably, one or more parameters of the bake step are altered by the control subsystem to reduce variation in the dimensions of patterned features formed on the wafer. The parameters fed forward to the additional bake module may be determined and altered by the control subsystem as described further herein.

In a further embodiment, as shown in FIG. 6, additional device 290 may be disposed within bake module 274. In this manner, additional device 290 may be configured to measure a characteristic of the patterned features formed on the wafer before, during, and/or after the bake step while wafer 212 is disposed within bake module 274. Additional device 290 may be configured according to any of the embodiments described herein. In addition, device 210 and additional device 290 may be configured similarly or differently. Furthermore, if additional devices 280, 288, and 290 are coupled to the lithography tool, some, all, or none of the additional devices may be configured similarly or differently.

Control subsystem 224 may be coupled to additional device 290 as shown by the dashed line in FIG. 6. Control subsystem 224 may be further coupled to additional device 290 as described herein. Control subsystem 224 may be configured to alter one or more parameters of the lithography process based on the characteristic of the patterned features measured by additional device 290. For example, control subsystem 224 may be configured to alter one or more parameters of bake module 274 based on a characteristic of the patterned features measured by the additional device. In this manner, the control subsystem may be configured to control the bake step by in situ and/or feedback control. Preferably, one or more parameters of the bake step are altered by the control subsystem to reduce variation in the dimensions of patterned features formed on additional wafers. The parameters of the additional bake module may be determined and altered by the control subsystem as described further herein.

In another example, control subsystem 224 may be configured to alter or determine one or more parameters of a different process such as etch to be performed on the wafer based on a characteristic of the patterned features measured by additional device 290. In this manner, the control subsystem may be configured to control an etch process based on the determined parameters or to send the determined parameters to an etch module (not shown) such that the etch module can use the determined parameters of the etch process for etching of wafer 212. In this manner, the control subsystem may be configured to control the etch process by feedforward control. Preferably, one or more parameters of the etch process are altered by the control subsystem to reduce variation in the dimensions of etched patterned features (not shown) formed on the wafer. The parameters of the etch module may be determined and altered as described further herein.

Another embodiment relates to a method for controlling variation in dimensions of patterned features across a wafer. The method includes measuring a characteristic of a latent image formed in a resist at more than one location across a wafer during a lithography process. Measuring the characteristic may be performed as described herein. The method also includes altering a parameter of the lithography process in response to the characteristic to reduce variation in dimensions of patterned features formed across the wafer by the lithography process. Altering the parameter compensates for non-time varying spatial variation in a temperature to which the wafer is exposed during a PEB step of the lithography process and an additional variation in the PEB step. Altering the parameter may be performed as described further herein.

In one embodiment, the additional variation includes time varying spatial variation in the temperature. In another embodiment, the additional variation includes variation in energy transfer to the wafer. In a further embodiment, the additional variation includes variation in time between an exposure step of the lithography process and initiation of the PEB step.

In an embodiment, the parameter includes the temperature to which different portions of the wafer are exposed during the PEB step. In another embodiment, the parameter includes a temperature to which different portions of the wafer are exposed during a bake step performed during the lithography process after the PEB step. In an additional embodiment, the parameter includes a parameter of a develop step performed during the lithography process after the PEB step.

In some embodiments, measuring the characteristic includes optically measuring the characteristic of the latent image. In another embodiment, measuring the characteristic includes optically measuring the characteristic of the latent image at more than one wavelength. In an additional embodiment, measuring the characteristic includes optically measuring the characteristic of the latent image across a spectrum of wavelengths. In a further embodiment, measuring the characteristic includes optically forming an image of the latent image and determining the characteristic from the image. In a different embodiment, measuring the characteristic includes measuring byproducts of the PEB step and determining the characteristic from the byproducts.

In some embodiments, measuring the characteristic includes measuring the characteristic of the latent image at the more than one location sequentially. In a different embodiment, measuring the characteristic includes measuring the characteristic of the latent image at the more than one location simultaneously. In a further embodiment, measuring the characteristic includes measuring the characteristic of the latent image during the PEB step.

Each of the steps of the method described above may be performed as described further herein. In addition, each of the embodiments of the method described above may include any other step(s) described herein. Furthermore, each of the embodiments of the method described above may be performed by any of the system embodiments described herein. Each of the embodiments of the method described above has all of the advantages of the system embodiments described herein.

The method embodiments described above may also include any other step(s) of the methods disclosed in U.S. Pat. No. 6,689,519 to Brown et al., which is incorporated by reference as if fully set forth herein. The systems described herein may be further configured as described in this patent. In addition, the systems described herein may be further configured as described in U.S. Pat. No. 6,483,580 to Xu et al. and U.S. Pat. No. 6,590,656 to Xu et al., which are incorporated by reference as if fully set forth herein. The method embodiments described above may also include any other step(s) described in these patents.

Further modifications and alternative embodiments of various aspects of the invention may be apparent to those skilled in the art in view of this description. For example, methods and systems for controlling variation in dimensions of patterned features across a wafer are provided. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A method for controlling variation in dimensions of patterned features across a wafer, comprising:
measuring a characteristic of a latent image formed in a resist at more than one location across a wafer during a lithography process; and
altering a parameter of the lithography process in response to the characteristic to reduce variation in dimensions of patterned features formed across the wafer by the lithography process, wherein said altering compensates for non-time varying spatial variation in a temperature to which the wafer is exposed during a post exposure bake step of the lithography process and an additional variation in the post exposure bake step, and wherein the additional variation comprises variation in time between an exposure step of the lithography process and initiation of the post exposure bake step.

2. The method of claim 1, wherein the additional variation further comprises time varying spatial variation in the temperature.

3. The method of claim 1, wherein the additional variation further comprises variation in energy transfer to the wafer.

4. The method of claim 1, wherein the parameter comprises the temperature to which different portions of the wafer are exposed during the post exposure bake step.

5. The method of claim 1, wherein the parameter comprises a temperature to which different portions of the wafer are exposed during a bake step performed during the lithography process after the post exposure bake step.

6. The method of claim 1, wherein the parameter comprises a parameter of a develop step performed during the lithography process after the post exposure bake step.

7. The method of claim 1, wherein said measuring comprises optically measuring the characteristic of the latent image.

8. The method of claim 1, wherein said measuring comprises optically measuring the characteristic of the latent image at more than one wavelength.

9. The method of claim 1, wherein said measuring comprises optically measuring the characteristic of the latent image across a spectrum of wavelengths.

10. The method of claim 1, wherein said measuring comprises optically forming an image of the latent image and determining the characteristic from the image.

11. The method of claim 1, wherein said measuring comprises measuring byproducts of the post exposure bake step and determining the characteristic from the byproducts.

12. The method of claim 1, wherein said measuring comprises measuring the characteristic of the latent image at the more than one location sequentially.

13. The method of claim 1, wherein said measuring comprises measuring the characteristic of the latent image at the more than one location simultaneously.

14. The method of claim 1, wherein said measuring comprises measuring the characteristic of the latent image during the post exposure bake step.

15. A system configured to control variation in dimensions of patterned features across a wafer, comprising:
a device configured to measure a characteristic of a latent image formed in a resist at more than one location across a wafer during a lithography process; and
a control subsystem configured to alter a parameter of the lithography process in response to the characteristic to reduce variation in dimensions of patterned features formed across the wafer by the lithography process, wherein altering the parameter compensates for non-time varying spatial variation in a temperature to which the wafer is exposed during a post exposure bake step of the lithography process and an additional variation in the post exposure bake step, and wherein the additional variation comprises variation in time between an exposure step of the lithography process and initiation of the post exposure bake step.

16. The system of claim 15, wherein the additional variation further comprises time varying spatial variation in the temperature.

17. The system of claim 15, wherein the additional variation further comprises variation in energy transfer to the wafer.

18. The system of claim 15, wherein the parameter comprises the temperature to which different portions of the wafer are exposed during the post exposure bake step.

19. The system of claim 15, wherein the parameter comprises a temperature to which different portions of the wafer are exposed during a bake step performed during the lithography process after the post exposure bake step.

20. The system of claim 15, wherein the parameter comprises a parameter of a develop step performed during the lithography process after the post exposure bake step.

21. The system of claim 15, wherein the device comprises an optical device.

22. The system of claim 15, wherein the device is further configured to measure the characteristic of the latent image at more than one wavelength.

23. The system of claim 15, wherein the device is further configured to measure the characteristic of the latent image across a spectrum of wavelengths.

24. The system of claim 15, wherein the device is further configured to optically form an image of the latent image and to determine the characteristic from the image.

25. The system of claim 15, wherein the device is further configured to measure byproducts of the post exposure bake step and to determine the characteristic of the latent image from the byproducts.

26. The system of claim 15, wherein the device is further configured to measure the characteristic of the latent image at the more than one location sequentially.

27. The system of claim 15, wherein the device is further configured to measure the characteristic of the latent image at the more than one location simultaneously.

28. The system of claim 15, wherein the device is further configured to measure the characteristic of the latent image during the post exposure bake step.
